(19) United States
(12) Patent Application Publication
(10) Pub. No.: US 2024/0238749 A1
(43) Pub. Date: Jul. 18, 2024

(54) MICROREACTOR AND PRODUCT PRODUCTION METHOD

(71) Applicant: HITACHI PLANT SERVICES CO., LTD., Tokyo (JP)

(72) Inventors: Yukako ASANO, Tokyo (JP); Masashi TAGAMI, Tokyo (JP); Takehiro CHIBA, Tokyo (JP)

(73) Assignee: HITACHI PLANT SERVICES CO., LTD., Tokyo (JP)

(21) Appl. No.: 18/579,807

(22) PCT Filed: Jun. 30, 2022
(86) PCT No.: PCT/JP2022/026435

§ 371 Date: Jan. 16, 2024

(30) Foreign Application Priority Data
Jul. 26, 2021 (JP) 2021-122035

(51) Int. Cl. B01J 19/00

(52) U.S. Cl. CPC B01J 19/0093; B01J 2219/00783; B01J 2219/00873; B01J 2219/00889

(57) ABSTRACT

A microreactor which reduces workload of an operator without risk of contamination by foreign substances such as a temperature control liquid. The microreactor produces a product by mixing at least two types of raw material and includes plates which are stacked on each other. One of the plates includes an inlet (first and second raw material inlets) which allows the raw material to be introduced into the inlet, a product outlet which allows a solution containing the product to be discharged from the outlet, a temperature control liquid inlet which allows a heat medium for temperature control to be introduced into the inlet, and a temperature control liquid outlet which allows the heat medium to be discharged from the outlet. The inlet, the product outlet, the temperature control liquid inlet, and the temperature control liquid outlet are located on the same face of the one of the plates.

### TECHNICAL FIELD

The present invention relates to a microreactor and a product production method using the same.

### BACKGROUND ART

The use of microreactors for mixing raw materials has recently been promoted in the fields of manufacturing bio-related products, pharmaceutical products, chemical products, and the like. A microreactor is a flow-type reactor having microchannels on the order of μm, and is used for mixing and reacting fluids. Microreactors are generally manufactured using microfabrication techniques such as molding and lithography. A replaceable detachable type and a disposable single-use type are also being considered.

In a microreactor, a microchannel is used as a reaction field, making it possible to rapidly mix fluids by molecular diffusion. Compared to a batch method using a large-sized reactor in the related art, the effect of the surface area relative to the volume of the fluid is relatively large. This allows for higher efficiency in heat transfer, heat conduction, reaction, and the like. Therefore, the microreactor can easily carry out reactions that may go out of control due to heat generation in normal batch reactions, reactions that require precise temperature control, and reactions that require rapid heating or cooling. With these characteristics, the application of microreactors is expected to shorten the reaction time and improve the reaction yield in various fields.

Such a microreactor, on the other hand, may be required to have a reaction channel provided for securing a residence time corresponding to the reaction time required for the reaction to proceed after a mixing channel for mixing raw materials. When increasing the production volume using a microreactor, in order to secure the same residence time, it is required to increase the length or cross-sectional area of the reaction channel, or to perform parallelization (also called N-fold or numbering-up) of channels of the same shape. In order to fully achieve the effect of the microreactor, various studies have been conducted regarding temperature control of fluids flowing through these channels.

For example, Patent Literature 1 discloses a microreactor including a laminate of a plurality of plates, in which passages are formed in the laminate by holes or grooves formed between the plates and/or in the plates. In this microreactor, the laminate has through-holes for positioning, which are provided in each plate. The through-holes are utilized to form heat medium and refrigerant channels for heating or cooling the fluid introduced into the channels. The laminate also has fixing plate members disposed at both ends thereof. These fixing plate members are tightened in an approaching direction with fasteners such as bolts and nuts, thus achieving polymerization of the plates.

Patent Literature 2 discloses a microreactor including: a reaction channel for reacting a plurality of raw material fluids with each other; and a temperature control channel for adjusting the temperatures of the raw material fluids flowing through the reaction channel. In this microreactor, the temperature control channel includes a plurality of first temperature control channel sections, each having a portion extending along a specific range of a reaction channel part on the downstream side from at least a junction part of the reaction channel. The temperature control channel also includes second temperature control channel sections, which are fewer than the first temperature control channel sections and connected to the downstream ends of the plurality of first temperature control channel sections. The second temperature control channel section has a cross-sectional area larger than that of each first temperature control channel section.

Patent Literature 3 discloses a microreactor including a mixing channel for mixing at least two types of raw material and a reaction channel connected to the downstream side of the mixing channel for causing a reaction of the mixture. In the microreactor, a channel for heat control is formed on a surface opposite to a surface where the reaction channel is formed. In this microreactor, a surface area/volume ratio (S/V ratio) of the reaction channel changes at least once as the mixture flows through the reaction channel. The surface area/volume ratio (S/V ratio) of the reaction channel is larger on the upstream side.

### CITATION LIST

### Patent Literature

Patent Literature 1: JP2013-208619A
Patent Literature 2: JP6190316
Patent Literature 3: JP4777383

### SUMMARY OF INVENTION

### Technical Problem

When increasing the production volume using a microreactor, however, it is not always the case that either one of the methods, including increasing the length of the reaction channel, increasing the cross-sectional area of the reaction channel, and parallelizing the same channels, can be used to secure the same residence time, and two or three of the methods are often used in combination. In terms of temperature controllability, it is easy to increase the length of the reaction channel in order to secure the residence time corresponding to the reaction time required for the reaction to proceed. When the reaction channel is increased in length, on the other hand, a single reaction channel plate (microreactor) of a portable size cannot accommodate the reaction channel, leading to the need for a plurality of reaction channel plates (microreactors).

Examples of a method for controlling the temperature of a plurality of reaction channel plates include 1) immersion in a constant temperature bath, 2) alternate stacking of reaction channel plates and temperature control plates, and the like. As for 1), when a microreactor includes two plates and these plates are tightened with fasteners such as bolts and nuts to form a reaction channel, insufficient tightening with the fasteners may cause a heat medium (temperature control liquid) for temperature control in the constant temperature bath to enter through a gap between the plates, leading to possible mixing of the temperature control liquid into raw materials and products. When introducing raw materials into the microreactor, a joint is used to connect the microreactor and a connecting tube. Insufficient tightening of the joint may cause the temperature control liquid in the constant temperature bath to enter through a gap therebetween. Moreover, since the materials have different thermal expansion coefficients, variations in temperature of the temperature control liquid may loosen the tightening of the fasteners and joint, leading to mixing of the temperature control liquid through gaps.

As for 2), the reaction channel plates and the temperature control plates are alternately stacked. This can prevent the temperature control liquid from entering the reaction channel plates. However, joints and connecting tubes for connecting the reaction channel plates and joints and connecting tubes for connecting the temperature control plates are required. The larger the number of reaction channel plates, the more complicated the handling becomes. When a plurality of reaction channel plates are used, these reaction channel plates are stacked in the same direction. Therefore, the inlet for the raw material and the outlet for the product are inevitably located in opposite directions. This leads to the need for accessing from two directions, the inlet side and the outlet side, when connecting the joints and connecting tubes to the inlet and outlet. This imposes restrictions on the installation location of the microreactor and the direction of accessing the microreactor. Therefore, as for 2), workload of an operator tends to increase.

Therefore, an object of the present invention is to provide a microreactor and a product production method, which can reduce workload of an operator without a risk of contamination by foreign substances such as a temperature control liquid.

### Solution to Problem

In response to the above issues, one or more aspects of the present invention are directed to a microreactor which produces a product by mixing at least two types of raw material, the microreactor including plates which are stacked on each other. One of the plates includes an inlet which allows the raw material to be introduced into the inlet, a product outlet which allows a solution containing the product to be discharged from the product outlet, a temperature control liquid inlet which allows a heat medium for temperature control to be introduced into the temperature control liquid inlet, and a temperature control liquid outlet which allows the heat medium to be discharged from the temperature control liquid outlet. The inlet, the product outlet, the temperature control liquid inlet, and the temperature control liquid outlet are located on the same face of the one of the plates.

### Advantageous Effects of Invention

The present invention can provide a microreactor and a product production method, which can reduce workload of an operator without a risk of contamination by foreign substances such as a temperature control liquid. Problems, configurations, and effects other than those described above will be clarified by the following description of the embodiments.

### BRIEF DESCRIPTION OF DRAWINGS

FIG. 1 is a perspective view showing an overall configuration of a microreactor according to an embodiment of the present invention.

FIG. 2 is an exploded view of the microreactor according to the embodiment of the present invention.

FIG. 3A is a front perspective view of a front cover plate in the microreactor according to the embodiment of the present invention.

FIG. 3B is a back perspective view of the front cover plate in the microreactor according to the embodiment of the present invention.

FIG. 3C is a front view of the front cover plate in the microreactor according to the embodiment of the present invention.

FIG. 3D is a back view of the front cover plate in the microreactor according to the embodiment of the present invention.

FIG. 4A is a front perspective view of a preheating plate in the microreactor according to the embodiment of the present invention.

FIG. 4B is a back perspective view of the preheating plate in the microreactor according to the embodiment of the present invention.

FIG. 4C is a front exploded perspective view of the preheating plate in the microreactor according to the embodiment of the present invention.

FIG. 4D is a front view of the preheating plate in the microreactor according to the embodiment of the present invention.

FIG. 4E is a back view of the preheating plate in the microreactor according to the embodiment of the present invention.

FIG. 5A is a front perspective view of a mixing plate in the microreactor according to the embodiment of the present invention.

FIG. 5B is a front exploded perspective view of the mixing plate in the microreactor according to the embodiment of the present invention.

FIG. 5C is a front view of the mixing plate in the microreactor according to the embodiment of the present invention.

FIG. 5D is a back view of the mixing plate in the microreactor according to the embodiment of the present invention.

FIG. 6 is an enlarged perspective view of section vi in FIG. 5B.

FIG. 7A is a front perspective view of a retention plate in the microreactor according to the embodiment of the present invention.

FIG. 7B is a back exploded perspective view of the retention plate in the microreactor according to the embodiment of the present invention.

FIG. 7C is a front view of the retention plate in the microreactor according to the embodiment of the present invention.

FIG. 7D is a back view of the retention plate in the microreactor according to the embodiment of the present invention.

FIG. 8A is a front perspective view of a back cover plate in the microreactor according to the embodiment of the present invention.

FIG. 8B is a front view of the back cover plate in the microreactor according to the embodiment of the present invention.

FIG. 8C is a back view of the back cover plate in the microreactor according to the embodiment of the present invention.

FIG. 9 is an exploded perspective view showing a configuration of channels and the flow of a fluid (liquid) in the microreactor according to the embodiment of the present invention.

FIG. 10 is a flowchart showing an example of a product production method according to an embodiment of the present invention.

FIG. 11 is a graph showing a pressure loss when pure water is sent to a PE microreactor manufactured in an example, wherein the horizontal axis represents a flow rate (mL/min) which is the sum of a flow rate of a first raw material and a flow rate of a second raw material, and the vertical axis represents the pressure loss (kPa) when pure water is sent to the microreactor.

### DESCRIPTION OF EMBODIMENTS

### <Microreactor>

Hereinafter, a microreactor according to an embodiment of the present invention will be described with reference to the drawings as appropriate.

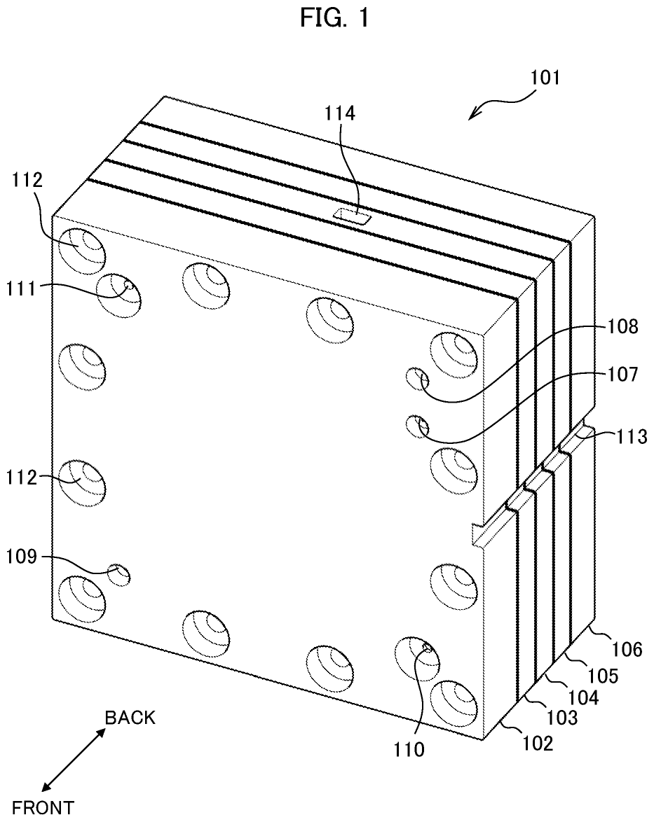

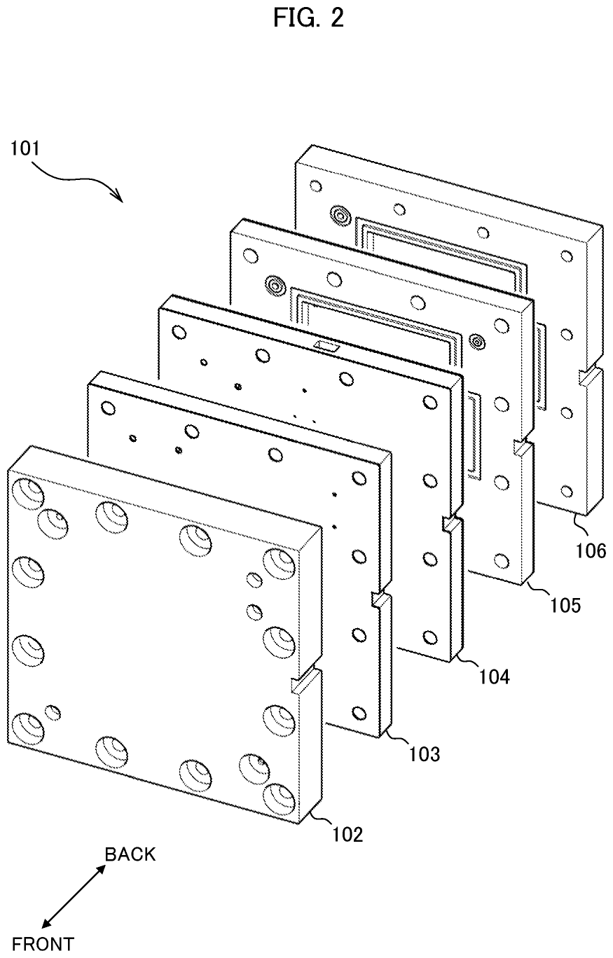

First, an overall configuration of a microreactor 101 according to the embodiment will be described with reference to FIGS. 1 and 2.

FIG. 1 is a perspective view showing the overall configuration of the microreactor 101 according to the embodiment of the present invention. FIG. 2 is an exploded view of the microreactor 101 according to the embodiment of the present invention.

As shown in FIGS. 1 and 2, the microreactor 101 according to this embodiment is configured by stacking a plurality of plates. Specifically, the microreactor 101 includes a front cover plate 102, a preheating plate 103, a mixing plate 104, a retention plate 105, a back cover plate 106, and various packings (not shown) provided between the plates. The microreactor 101 is used to produce a product by mixing at least two types of raw material. In this embodiment, description is given of a case where a product is obtained by mixing two types of raw material.

In the microreactor 101, a first raw material is introduced from a first raw material inlet 107 on the front cover plate 102. A second raw material is also introduced from a second raw material inlet 108 on the front cover plate 102. The first raw material and the second raw material pass through the preheating plate 103, respectively, and are joined and mixed together in the mixing plate 104. The raw materials mixed in the mixing plate 104 are introduced into the retention plate 105 where the mixing of the first and second raw materials proceeds to produce a product. When the first and second raw materials are mixed, if a reaction progresses, the reaction starts after the first and second raw materials are joined in the mixing plate 104, and the reaction further proceeds in the retention plate 105. The resultant product is discharged from the retention plate 105, through the mixing plate 104 and the preheating plate 103, and out through a product outlet 109 on the front cover plate 102.

In order to mix the first and second raw materials at a predetermined temperature, a heat medium for temperature control (temperature control liquid) is introduced from a temperature control liquid inlet 110 on the front cover plate 102. A temperature control liquid channel is formed in the microreactor 101 through which the temperature control liquid flows. The temperature control liquid introduced from the temperature control liquid inlet 110 reaches the back cover plate 106 through the preheating plate 103, the mixing plate 104, and the retention plate 105. The temperature control liquid is then discharged from a temperature control liquid outlet 111 on the front cover plate 102 through the retention plate 105, the mixing plate 104, and the preheating plate 103.

In the microreactor 101, in other words, one of the plurality of plates (specifically, the front cover plate 102) includes, on the same surface, inlets (a first raw material inlet 107 and a second raw material inlet 108) for introducing the raw materials, the product outlet 109 for discharging a solution containing the product, the temperature control liquid inlet 110 for introducing the heat medium, and the temperature control liquid outlet 111 for discharging the heat medium.

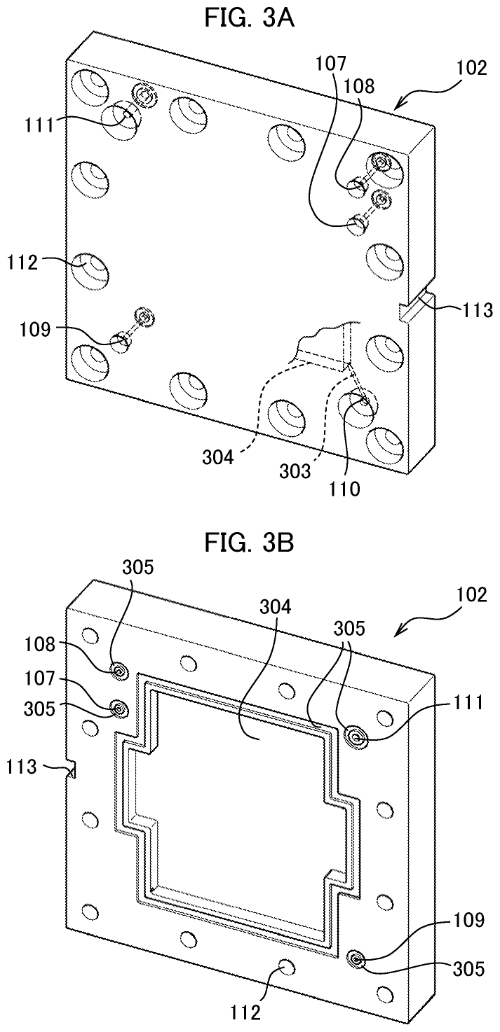

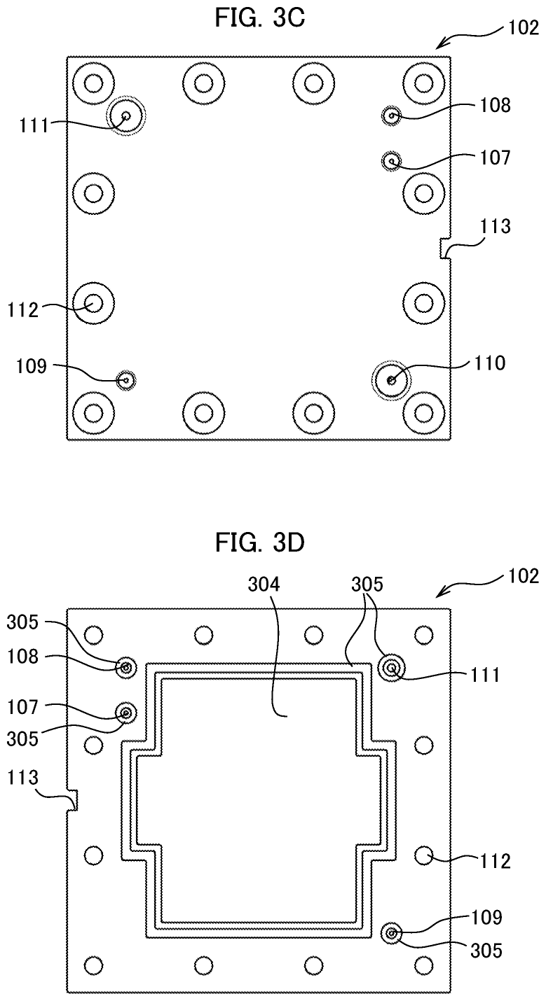

The configuration and details of each channel in the microreactor 101 will be described later with reference to FIGS. 3A to 9.

The first and second raw materials and the temperature control liquid are introduced by some kind of liquid feeder. Examples of the liquid feeder include syringe pumps, manual syringes, plunger pumps, diaphragm pumps, screw pumps, and the like. The liquid feeder may use a head difference. The first raw material inlet 107, the second raw material inlet 108, and the temperature control liquid inlet 110 may be connected to some kind of liquid feeder using joints and connecting tubes (none of which are shown). This some kind of liquid feeder can be any of those described above. The product outlet 109 and the temperature control liquid outlet 111 may also be connected to some kind of container using joints and connecting tubes (none of which are shown). Examples of some kind of container include a 2D bag, a 3D bag, a bottle with a cap, a chemical tanks, and the like. The temperature control liquid inlet 110 and the temperature control liquid outlet 111 can be connected to the outlet and inlet of a circulating constant temperature bath equipped with a pump, respectively, so that the temperature can be controlled while circulating the temperature control liquid.

The type of the temperature control liquid can be changed as needed according to a reaction temperature to be set. The temperature control liquid can be, for example, a liquid at the reaction temperature to be set, such as water, a water-ethanol mixed solvent, and ethylene glycol. When the reaction temperature is room temperature, the temperature control liquid may not necessarily be required depending on the heat of mixing or reaction from the first raw material and the second raw material and the thermal controllability of the microreactor 101.

For good mixing in the microreactor 101, the channel in the microreactor 101 preferably has a representative diameter of 2 mm or less. Immediately before and after the merging of the first and second raw materials, in particular, the representative diameter of the channel is preferably in the range of several tens μm to 1 mm, in order to quickly mix the two types of raw material by molecular diffusion. In the microreactor 101, the two types of raw material may be evenly mixed or may be unevenly mixed (in a so-called emulsified state).

The material of the microreactor 101 can be changed as needed according to the type of reaction, as long as the material does not adversely affect the mixing and reaction. The microreactor 101 can be formed using, for example, stainless steel, silicon, gold, glass, hastelloy, silicon resin, acrylic, polycarbonate (PC), cycloolefin polymer (COP), polyethylene (PE), polypropylene (PP), methyltenpen polymer (TPX), fluorine-based resin, polyetheretherketone resin (PEEK), or the like. The microreactor 101 can also be formed of a material with improved corrosion resistance, such as metal with a glass-lined surface, metal with its surface coated with nickel, gold, or the like, or silicon with an oxidized surface.

When a tube pump or a syringe pump is used as some kind of liquid feeder described above, various kinds of resin such as silicon resin, acrylic, polycarbonate (PC), cycloolefin polymer (COP), polyethylene (PE), polypropylene (PP), fluorine-based resin, and polyetheretherketone resin (PEEK) can be used as the material of the connecting tube, joint connecting the microreactor 101 and the connecting tube, syringe, pump head, and the like, which serve as liquid contact parts. Such various kinds of resin can also be used for some kind of container described above, which serves as the liquid contact part. In a system including the microreactor 101 with such a configuration, only the liquid contact part including the microreactor 101 can be single-use (disposable). The materials of the liquid contact parts do not need to be the same and can be changed as needed according to the workability of the microreactor 101 and the flexibility of the tubes. The liquid contact part of the temperature control liquid does not necessarily have to be single-use and can be reused as needed.

The front cover plate 102, the preheating plate 103, the mixing plate 104, the retention plate 105, and the back cover plate 106, which constitute the microreactor 101, have twelve screw holes 112 formed therein for stacking and screwing the respective plates. The plates can thus be stacked, fixed with screws and the screw holes 112 or disassembled. To prevent the screws from loosening, a plain washer (washer) may be inserted between the screw bearing surface and clamping part, or a loose stopper nut may be attached to the tip of the screw. The screws and screw holes 112 also play a positioning role when stacking the plates, but a through-hole for positioning may be further added between the screw holes 112. The plates may be stacked so that they cannot be disassembled, by various welding methods such as adhesion, fusion welding, pressure welding, ultrasonic welding, vibration welding, induction welding, high frequency welding, and laser welding.

Each of these plates constituting the microreactor 101 has a notch 113 formed therein to identify the orientation when the plates are stacked. The notch 113 does not, however, necessarily have to be formed.

A thermocouple insertion port 114 is formed to measure the temperature around the junction of the first and second raw materials in the mixing plate 104. When the heat of mixing or reaction of the first and second raw materials is large, it is preferable that a thermocouple is inserted into the thermocouple insertion port 114 to measure the temperature near the junction. When the reaction temperature to be set is close to room temperature, when the microreactor 101 has high thermal controllability, when the flow rate of the temperature control liquid is high, or the like, on the other hand, the thermocouple insertion port 114 may not always be necessary.

Next, with reference to FIGS. 3A to 9, description is given of the front cover plate 102, preheating plate 103, mixing plate 104, retention plate 105, and back cover plate 106 that constitute the microreactor 101 according to this embodiment.

FIGS. 3A to 3D are, respectively, a front perspective view, a back perspective view, a front view, and a back view of the front cover plate 102 in the microreactor 101 according to the embodiment of the present invention.

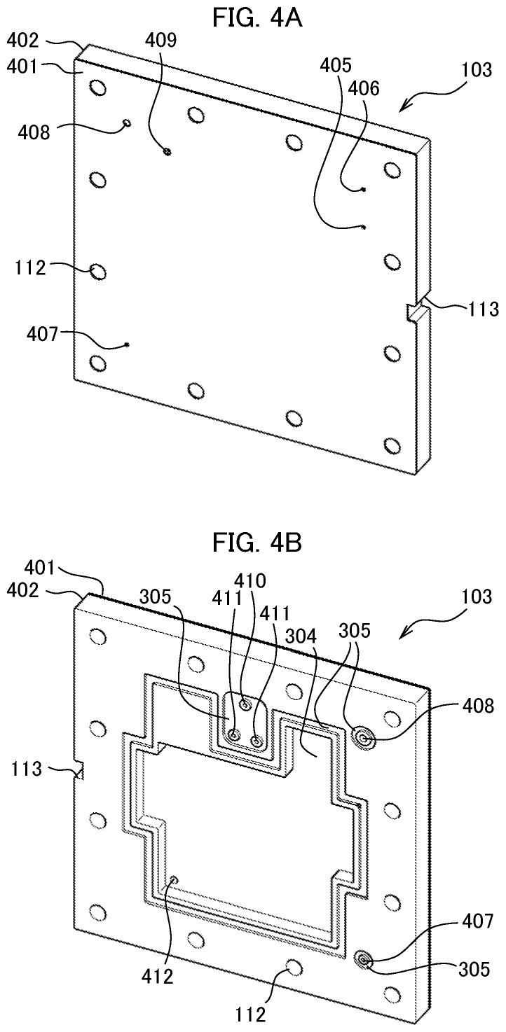

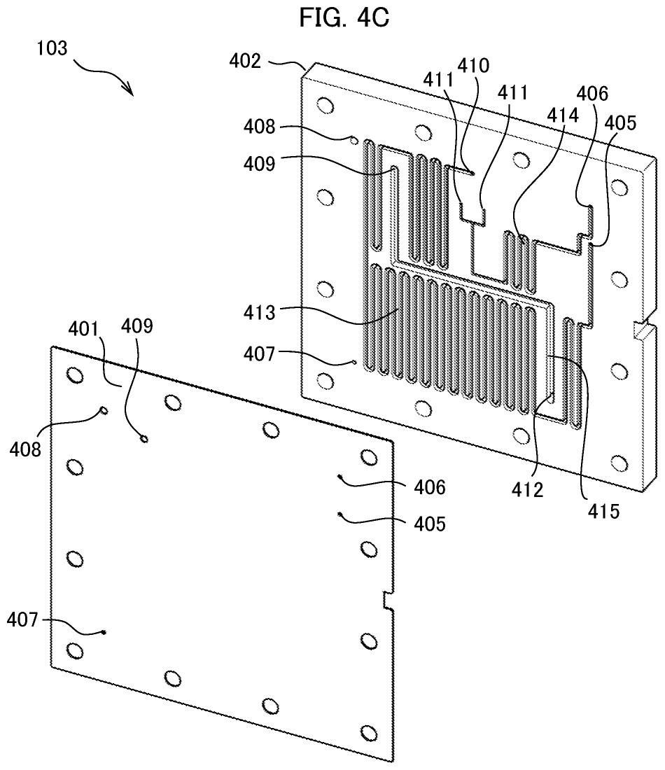

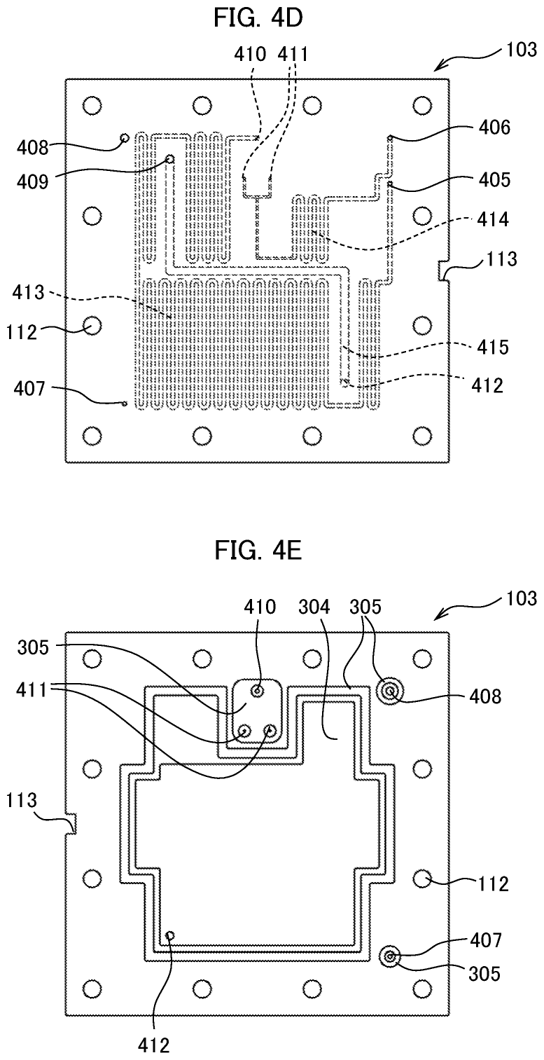

FIGS. 4A to 4E are, respectively, a front perspective view, a back perspective view, a front exploded perspective view, a front view, and a back view of the preheating plate 103 in the microreactor 101 according to the embodiment of the present invention.

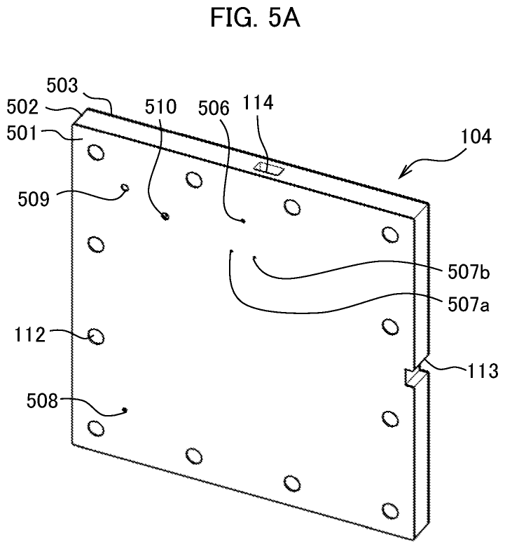

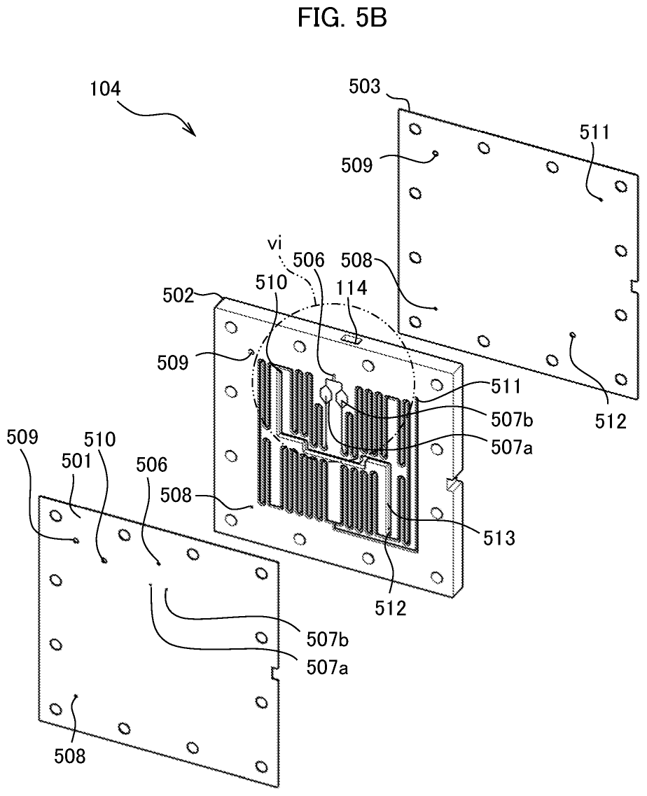

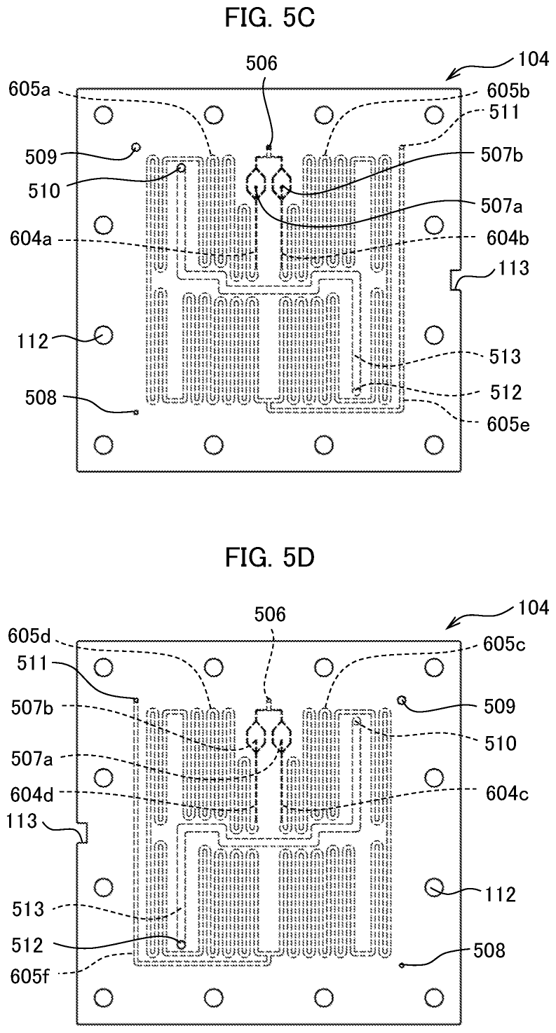

FIGS. 5A to 5D are, respectively, a front perspective view, a front exploded perspective view, a front view, and a back view of the mixing plate 104 in the microreactor 101 according to the embodiment of the present invention.

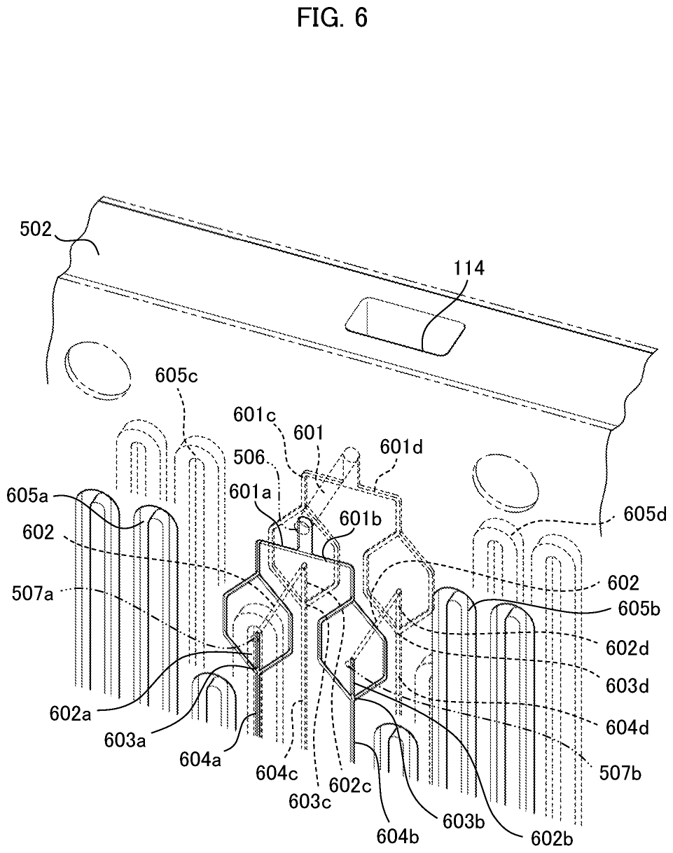

FIG. 6 is an enlarged perspective view of section vi in FIG. 5B.

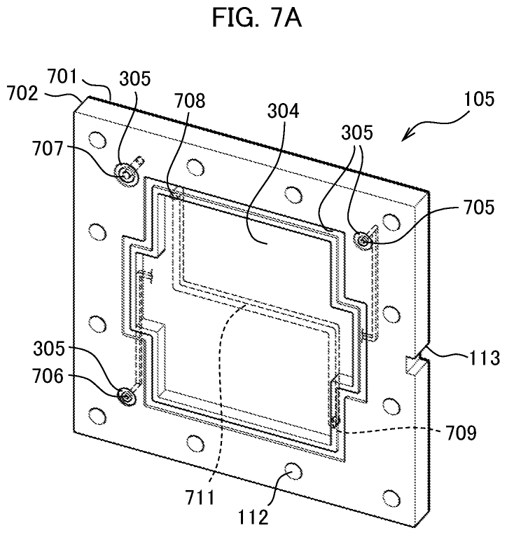

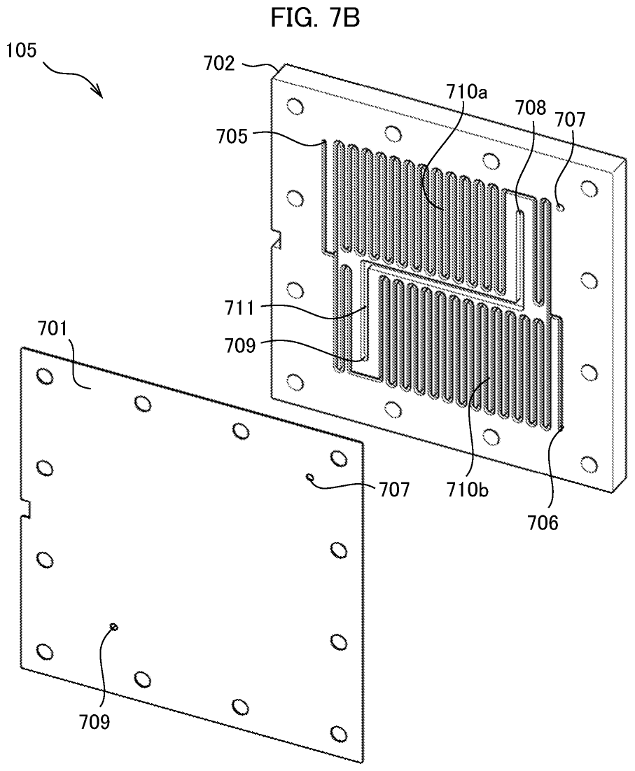

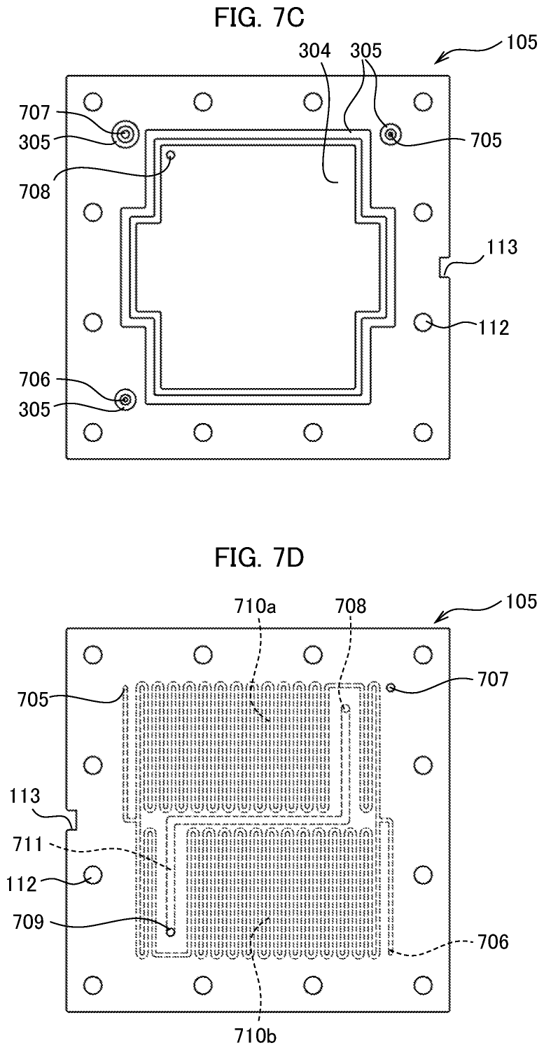

FIGS. 7A to 7D are, respectively, a front perspective view, a back exploded perspective view, a front view, and a back view of the retention plate 105 in the microreactor 101 according to the embodiment of the present invention.

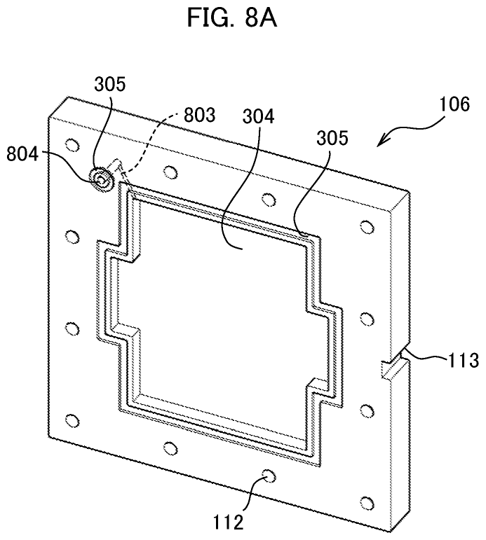

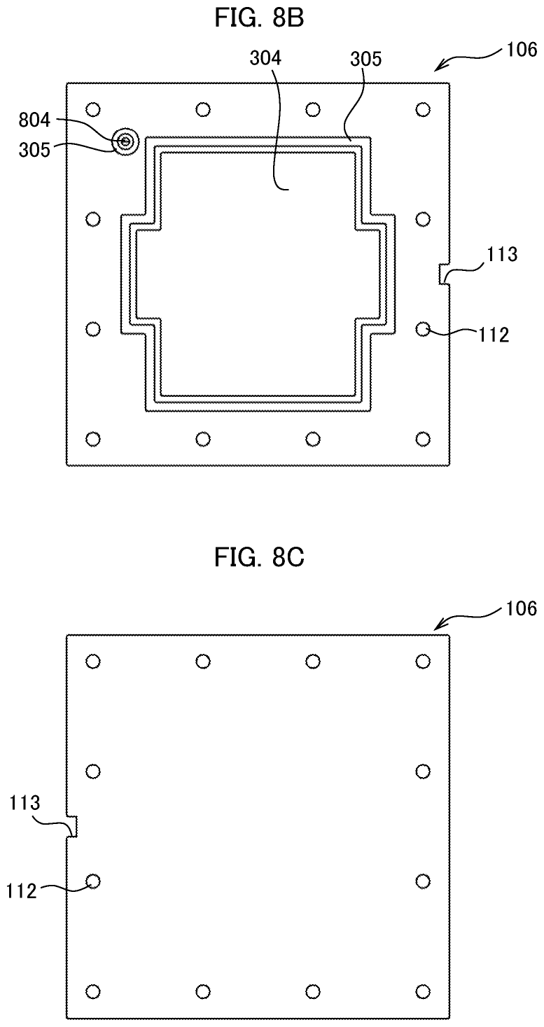

FIGS. 8A to 8C are, respectively, a front perspective view, a front view, and a back view of the back cover plate 106 in the microreactor 101 according to the embodiment of the present invention.

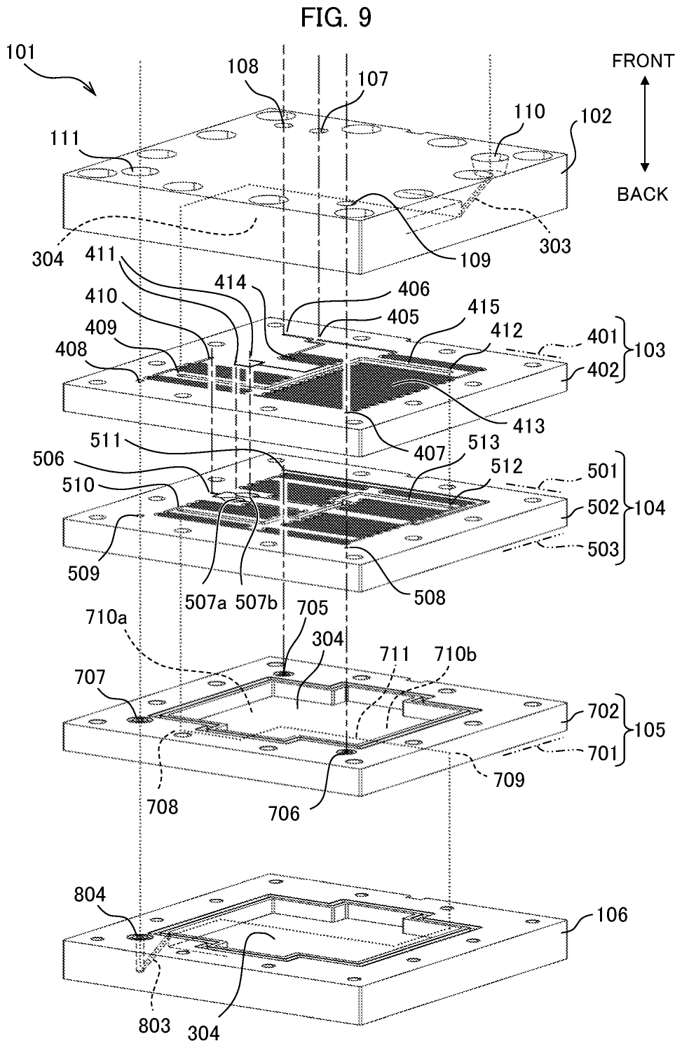

FIG. 9 is an exploded perspective view showing the configuration of channels and the flow of a fluid (liquid) in the microreactor 101 according to the embodiment of the present invention.

### <Front Cover Plate>

As shown in FIGS. 3A to 3D, the first raw material inlet 107, the second raw material inlet 108, the product outlet 109, and the temperature control liquid outlet 111, which penetrate to the back side, are formed on the front side of the front cover plate 102. The temperature control liquid inlet 110, which does not penetrate to the back side, is formed on the front side of the front cover plate 102. The twelve screw holes 112 penetrating to the back side for screwing the stacked plates are formed on the front side of the front cover plate 102.

As shown in FIGS. 3A and 3C, the first raw material inlet 107 and the second raw material inlet 108 are formed in the upper right part on the front side of the front cover plate 102. In this embodiment, the second raw material inlet 108 is formed above the first raw material inlet 107 in FIGS. 3A and 3C.

As shown in FIGS. 3A and 3C, the product outlet 109 is formed in the lower left part on the front side of the front cover plate 102.

As shown in FIGS. 3A and 3C, the temperature control liquid outlet 111 is formed in the upper left part on the front side of the front cover plate 102.

The temperature control liquid inlet 110 is formed in the lower right part on the front side of the front cover plate 102, as shown in FIGS. 3A and 3C.

The screw holes 112 are formed at regular intervals along the outer edge of the front cover plate 102 on the front side of the front cover plate 102, as shown in FIGS. 3A and 3C.

As shown in FIGS. 3B and 3D, a temperature control liquid channel 304 and the first raw material inlet 107, second raw material inlet 108, product outlet 109, and temperature control liquid outlet 111, which penetrate from the front side, are formed on the back side of the front cover plate 102. As shown in FIGS. 3B and 3D, the temperature control liquid channel 304 in the front cover plate 102 is formed in a substantially cross-shape or substantially rectangular shape with a large area in the middle, on the back side of the front cover plate 102.

A packing groove 305 is formed around each of the temperature control liquid channel 304, the first raw material inlet 107, the second raw material inlet 108, the product outlet 109, and the temperature control liquid outlet 111 on the back side of the front cover plate 102.

Moreover, in the front cover plate 102, as shown in FIG. 3A, a channel 303, which does not penetrate to the back side, is also formed from the temperature control liquid inlet 110 to the temperature control liquid channel 304. The temperature control liquid introduced from the temperature control liquid inlet 110 is introduced from the temperature control liquid inlet 110 to the temperature control liquid channel 304 through the channel 303.

### <Preheating Plate>

As shown in FIGS. 4A and 4C, the preheating plate 103 includes a preheating plate upper plate 401 and a preheating plate lower plate 402. Only holes are formed in the preheating plate upper plate 401. Holes and grooves are formed in the preheating plate lower plate 402 on both of the surface on the preheating plate upper plate 401 side and the surface opposite thereto. Therefore, by integrating the preheating plate upper plate 401 and the preheating plate lower plate 402, a channel is formed by the preheating plate upper plate 401 and the surface of the preheating plate lower plate 402 on the preheating plate upper plate 401 side.

The preheating plate upper plate 401 and the preheating plate lower plate 402 can be integrated without using any packing by various kinds of welding such as adhesion, fusion welding, pressure welding, ultrasonic welding, vibration welding, induction welding, high frequency welding, laser welding, and laser transmission welding. Among these, laser transmission welding can be suitably applied, for example, in this embodiment. The laser transmission welding uses a light-transmitting resin that transmits a laser beam and a light-absorbing resin that generates heat by absorbing the laser beam transmitted through the light-transmitting resin. The upper and lower plates are welded by irradiating a laser beam from the light-transmitting resin side. The light-absorbing resin contains a pigment-based absorbing pigment and/or a dye-based absorbing pigment. These absorbing pigments absorb the laser beam and generate heat. Therefore, the light-transmitting resin is often white or colorless resin and the light-absorbing resin is colored resin such as black.

The only difference between the light-transmitting resin and the light-absorbing resin is whether or not the absorbing pigments are contained therein, and the same resin can be used as the base material for both. Examples of the resin that can be used for both include but are not limited to polypropylene (PP), polyethylene (PE), polybutylene terephthalate (PBT), polyethylene terephthalate (PET), polyamide (PA), polyacetal (POM), polyphenyl sulfide (PPS), polystyrene (PS), low density polyethylene (LDPE), polycarbonate (PC), polymethyl methacrylate (PMMA), polyarylate (PAR), polysulfone (PSF), polyethersulfone (PES), and the like. In this embodiment, for example, it is preferable that white PE resin, white PP resin or white PC resin is used as the material of the preheating plate upper plate 401 and colored PE resin, colored PP resin or colored PC resin such as black is used as the material of the preheating plate lower plate 402. It is more preferable that white PE resin or white PP resin is used as the material of the preheating plate upper plate 401 and colored PE resin or colored PP resin is used as the material of the preheating plate lower plate 402. Such preheating plate upper plate and preheating plate lower plate can be integrated by laser welding to obtain the preheating plate 103 with corrosion resistance. The preheating plate 103 can be thus protected from contamination by foreign materials such as an adhesive or the temperature control liquid from outside into the channel.

As shown in FIGS. 4A and 4D, a first raw material inlet (preheating plate) 405 and a second raw material inlet (preheating plate) 406, which do not penetrate to the back side, are provided on the front side of preheating plate 103.

A product channel (preheating plate) 407 and a temperature control liquid channel (preheating plate) 408, which penetrate to the back side, are formed on the front side of the preheating plate 103.

A temperature control liquid inlet (preheating plate) 409, which does not penetrate to the back side, is formed on the front side of the preheating plate 103.

Twelve screw holes 112 penetrating to the back side for screwing the stacked plates are formed on the front side of the preheating plate 103.

As shown in FIGS. 4A and 4D, the first raw material inlet (preheating plate) 405 and the second raw material inlet (preheating plate) 406 are formed in the upper right part on the front side of the preheating plate 103. In this embodiment, the second raw material inlet (preheating plate) 406 is formed above the first raw material inlet (preheating plate) 405 in FIGS. 4A and 4D.

The product channel (preheating plate) 407 is formed in the lower left part on the front side of the preheating plate 103, as shown in FIGS. 4A and 4D.

As shown in FIGS. 4A and 4D, the temperature control liquid channel (preheating plate) 408 and the temperature control liquid inlet (preheating plate) 409 are formed in the upper left part on the front side of the preheating plate 103. In this embodiment, the temperature control liquid channel (preheating plate) 408 is formed outside the temperature control liquid inlet (preheating plate) 409 in FIGS. 4A and 4D.

As shown in FIGS. 4A and 4D, the screw holes 112 are formed at regular intervals along the outer edge of the preheating plate 103 on the front side of the preheating plate 103.

As shown in FIGS. 4B and 4E, the temperature control liquid channel 304, a first raw material outlet (preheating plate) 410, a second raw material outlet (preheating plate) 411, and a temperature control liquid outlet (preheating plate) 412 are formed on the back side of the preheating plate 103.

The temperature control liquid outlet (preheating plate) 412 is communicated with the temperature control liquid inlet (preheating plate) 409 on the front side through a temperature control liquid channel 415, as shown in FIG. 4D.

The temperature control liquid channel 415 is formed from the temperature control liquid inlet (preheating plate) 409 to the temperature control liquid outlet (preheating plate) 412. The temperature control liquid channel 415 is bent substantially at a right angle, but does not need to be bent as long as the temperature control liquid inlet (preheating plate) 409 and the temperature control liquid outlet (preheating plate) 412 are communicated with each other.

As shown in FIGS. 4B and 4E, the temperature control liquid channel 304 in the preheating plate 103 is formed in a substantially rectangular shape with a larger area toward the lower side from substantially the center on the back side of the preheating plate 103.

As shown in FIGS. 4B and 4E, on the back side of the preheating plate 103, a packing groove 305 is formed around each of the product channel (preheating plate) 407, the temperature control liquid channel (preheating plate) 408, the temperature control liquid channel 304, the first raw material outlet (preheating plate) 410, and the second raw material outlet (preheating plate) 411. The packing groove 305 around the temperature control liquid channel 304 has a portion that is not along the circumference of the temperature control liquid channel 304. This is for the temperature control liquid to flow smoothly when the preheating plate 103, in particular, is installed so that the first raw material outlet (preheating plate) 410 and the second raw material outlet (preheating plate) 411 face upward, as shown in FIGS. 4B and 4D. With the packing groove 35 having a symmetrical shape, the preheating plate 103 can evenly apply force during screwing.

By stacking the plates as shown in FIGS. 1, 2, and 9 with various packings (not shown) interposed between the plates, the surface of the front cover plate 102 on the preheating plate 103 side and the surface of the preheating plate 103 on the front cover plate 102 side form the temperature control liquid channel 304, and the channels in the front cover plate 102 and the preheating plate 103 are communicated with each other. The first raw material inlet (preheating plate) 405 is communicated with the first raw material inlet 107 in the front cover plate 102. The second raw material inlet (preheating plate) 406 is communicated with the second raw material inlet 108 in the front cover plate 102. The product channel (preheating plate) 407 is communicated with the product outlet 109 in the front cover plate 102. The temperature control liquid channel (preheating plate) 408 is communicated with the temperature control liquid outlet 111 in the front cover plate 102. The temperature control liquid inlet (preheating plate) 409 is communicated with the temperature control liquid channel 304 in the front cover plate 102.

As shown in FIGS. 4D and 4E, the first raw material introduced from the first raw material inlet (preheating plate) 405 on the front side is discharged from the first raw material outlet (preheating plate) 410 on the back side through the first raw material channel 413. The first raw material channel 413 extends from the first raw material inlet (preheating plate) 405 to a predetermined section (lower section) of the preheating plate 103, and is folded a predetermined number of times within that section. The first raw material channel 413 then extends to another predetermined section (upper section) of the preheating plate 103 and is communicated with the first raw material outlet (preheating plate) 410 after being folded a predetermined number of times within that section.

The second raw material introduced from the second raw material inlet (preheating plate) 406 on the front side is discharged from two second raw material outlets (preheating plate) 411 through a second raw material channel 414 branching into two channels. The second raw material channel 414 is folded a predetermined number of times in the aforementioned another predetermined section (upper section) of the preheating plate 103, and then communicated with the two second raw material outlets (preheating plate) 411.

The temperature control liquid introduced from the temperature control liquid inlet (preheating plate) 409 is discharged to the temperature control liquid channel 304 from the temperature control liquid outlet (preheating plate) 412 through the temperature control liquid channel 415.

That is, in the microreactor 101, one of the plurality of plates (specifically, the preheating plate 103) has a channel (first raw material channel 413 and/or second raw material channel 414), through which at least one type of raw material flows, on one surface (front side), and also has a channel (temperature control liquid channel 304), through which the heat medium flows, on a surface (back side) opposite to the surface described above.

When the channel internal volume (inner volume) of the first raw material channel 413 and the second raw material channel 414 is too small, the first raw material and the second raw material are introduced into the mixing plate 104 before reaching a predetermined temperature. Therefore, it is preferable that the representative diameter and length of the first raw material channel 413 and the second raw material channel 414 are selected accordingly based on the reaction temperature to be set in the microreactor 101, the thermal controllability of the microreactor 101, the flow rate of the temperature control liquid, and the like. The number of the preheating plates 103 is not limited to one, and a plurality of plates may be used. When the reaction temperature to be set in the microreactor 101 is close to room temperature and the heat of mixing or reaction of the first and second raw materials is small, the first and second raw materials can be controlled in some cases to a predetermined temperature before merging in the mixing plate 104 to be described later. In such a case, the preheating plate 103 does not sometimes need to be used.

The relationship between the channel internal volume of the first raw material channel 413 and the second raw material channel 414 and the flow rate ratio (volume ratio) of the two types of raw material will be described in the description of the mixing plate 104.

### <Mixing Plate>

As shown in FIGS. 5A and 5B, the mixing plate 104 includes a mixing plate upper plate 501, a mixing plate middle plate 502, and a mixing plate lower plate 503. Only holes are formed in the mixing plate upper plate 501 and the mixing plate lower plate 503. Holes and grooves are formed in the mixing plate middle plate 502 on both of the surface on the mixing plate upper plate 501 side and the surface on the mixing plate lower plate 503 side. Therefore, by integrating the mixing plate upper plate 501, the mixing plate middle plate 502, and the mixing plate lower plate 503, a channel is formed by the mixing plate upper plate 501 and the surface of the mixing plate middle plate 502 on the mixing plate upper plate 501 side. A channel is also formed by the mixing plate lower plate 503 and the surface of the mixing plate middle plate 502 on the mixing plate lower plate 503 side.

The mixing plate upper plate 501, the mixing plate middle plate 502, and the mixing plate lower plate 503 can be integrated without using any packing by various kinds of welding such as adhesion, fusion welding, pressure welding, ultrasonic welding, vibration welding, induction welding, high frequency welding, laser welding, and laser transmission welding, as in the case of the preheating plate upper plate 401 and the preheating plate lower plate 402. Among these, laser transmission welding using a light-transmitting resin and a light-absorbing resin can be suitably applied in this embodiment, as in the case of the preheating plate 103. The light-transmitting resin and the light-absorbing resin have already been described, and thus description thereof will be omitted here. In this embodiment, for example, it is preferable that white PE resin, white PP resin, or white PC resin is used as the material of the mixing plate upper plate 501 and the mixing plate lower plate 503. It is also preferable that colored PE resin, colored PP resin, or colored PC resin such as black is used as the material of the mixing plate middle plate 502. It is more preferable that white PE resin or white PP resin is used as the material of the mixing plate upper plate 501 and the mixing plate lower plate 503, and that colored PE resin or colored PP resin is used as the material of the mixing plate middle plate 502. Such mixing plate upper plate, mixing plate middle plate, and mixing plate lower plate can be integrated by laser welding to obtain the mixing plate 104 with corrosion resistance. The mixing plate 104 can be thus protected from contamination by foreign materials such as an adhesive or the temperature control liquid from outside into the channel.

As shown in FIGS. 5A and 5C, a first raw material inlet (mixing plate) 506 penetrating to the mixing plate middle plate 502 and two second raw material inlets (mixing plate) 507a and 507b penetrating to the mixing plate middle plate 502 are formed on the front side of the mixing plate 104.

On the front side of the mixing plate 104, a product channel (mixing plate) 508 and a temperature control liquid channel (mixing plate) 509 are formed, which penetrate to the back side.

A temperature control liquid inlet (mixing plate) 510, which does not penetrate to the back side, is formed on the front side of the mixing plate 104.

Twelve screw holes 112 penetrating to the back side for screwing the stacked plates are formed on the front side of the mixing plate 104.

The first raw material inlet (mixing plate) 506 and the second raw material inlets (mixing plate) 507a and 507b are in the upper center part on the front side of the mixing plate 104, as shown in FIGS. 5A and 5C. In this embodiment, the first raw material inlet (mixing plate) 506 is formed above the second raw material inlets (mixing plates) 507a and 507b in FIGS. 5A and 5C.

A product channel (mixing plate) 508 is formed in the lower left part on the front side of the mixing plate 104 as shown in FIGS. 5A and 5C.

As shown in FIGS. 5A and 5C, a temperature control liquid channel (mixing plate) 509 and a temperature control liquid inlet (mixing plate) 510 are formed in the upper left part on the front side of the mixing plate 104. In this embodiment, the temperature control liquid channel (mixing plate) 509 is formed outside the temperature control liquid inlet (mixing plate) 510 in FIGS. 5A and 5C.

The screw holes 112 are formed at regular intervals along the outer edge of the mixing plate 104 on the front side of the mixing plate 104, as shown in FIGS. 5A and 5C.

As shown in FIG. 5D, a product outlet (mixing plate) 511 and a temperature control liquid outlet (mixing plate) 512 are formed on the back side of the mixing plate 104. As shown in FIGS. 5C and 5D, the temperature control liquid outlet (mixing plate) 512 is communicated with the temperature control liquid inlet (mixing plate) 510 on the front side through a temperature control liquid channel 513. The temperature control liquid channel 513 is formed from the temperature control liquid inlet (mixing plate) 510 to the temperature control liquid outlet (mixing plate) 512. The temperature control liquid channel 513 is bent substantially at a right angle, but does not need to be bent as long as the temperature control liquid inlet (mixing plate) 510 and the temperature control liquid outlet (mixing plate) 512 are communicated with each other. The product channel (mixing plate) 508 and the temperature control liquid channel (mixing plate) 509, which penetrate from the front side, are formed on the back side of the mixing plate 104. Moreover, twelve screw holes 112 penetrating to the front side for screwing the stacked plates are formed on the back side of the mixing plate 104.

The product outlet (mixing plate) 511 is formed in the upper left part on the back side of the mixing plate 104 as shown in FIG. 5D.

The temperature control liquid outlet (mixing plate) 512 is formed in the lower left part on the back side of the mixing plate 104 as shown in FIG. 5D.

The product channel (mixing plate) 508 is formed in the lower right part on the back side of the mixing plate 104 as shown in FIG. 5D.

The temperature control liquid channel (mixing plate) 509 is formed in the upper right part on the back side of the mixing plate 104, as shown in FIG. 5D.

The screw holes 112 are formed at regular intervals along the outer edge of the mixing plate 104 on the back side of the mixing plate 104, as shown in FIG. 5D.

By stacking the plates as shown in FIGS. 1, 2, and 9 with various packings (not shown) interposed between the plates, the surface of the preheating plate 103 on the mixing plate 104 side and the surface of the mixing plate 104 on the preheating plate 103 side form the temperature control liquid channel 304, and the channels in the preheating plate 103 and the mixing plate 104 are communicated with each other. The first raw material inlet (mixing plate) 506 is communicated with the first raw material outlet (preheating plate) 410 in the preheating plate 103. The two second raw material inlets (mixing plate) 507a and 507b are communicated with the two second raw material outlets (preheating plate) 411 and 411 in the preheating plate 103. The product channel (mixing plate) 508 is communicated with the product channel (preheating plate) 407 in the preheating plate 103. The temperature control liquid channel (mixing plate) 509 is communicated with the temperature control liquid channel (preheating plate) 408 in the preheating plate 103.

As shown in FIG. 6, symmetrical mixing channels 604a and 604b for merging and mixing the first raw material and the second raw material are formed on the front side of the mixing plate 104. On the downstream side of the respective mixing channels 604a and 604b, retention channels 605a and 605b having the same channel internal volume (inner volume) are provided for advancing the mixing of the first and second raw materials. In the mixing plate 104, two channels for mixing the raw materials are provided in parallel on the front side.

Moreover, as shown in FIG. 6, symmetrical mixing channels 604c and 604d for merging and mixing the first raw material and the second raw material are formed on the back side of the mixing plate 104. On the downstream side of the respective mixing channels 604c and 604d, retention channels 605c and 605d having the same channel internal volume (inner volume) are provided for advancing the mixing of the first and second raw materials. In the mixing plate 104, two channels for mixing the raw materials are provided in parallel on the back side.

In the mixing plate 104, therefore, four channels for mixing the raw materials are provided in parallel on the front side and the back side.

In other word, in the microreactor 101, one of the plurality of plates (specifically, the mixing plate 104) has channels (mixing channels 604a, 604b, 604c, and 604d) for mixing at least two types of raw material on one surface (front side) and a surface (back side) opposite to the surface. In the microreactor 101, one of the plurality of plates (specifically, the mixing plate 104) has retention channels 605a, 605b, 605c, and 605d one surface (front side) and a surface (back side) opposite to the surface.

As shown in FIG. 6, a first raw material channel 601 continuing from the first raw material inlet (mixing plate) 506 branches into two channels on the front side and the back side, and then each of the channels on the front side and the back side branches into two channels, resulting in four first raw material channels 601a, 601b, 601c, and 601d. Accordingly, the first raw material is also divided into four channels.

A second raw material channel 602 continuing from the two second raw material inlets (mixing plates) 507a and 507b branches into two channels on the front side and the back side, respectively, resulting in four second raw material channels 602a, 602b, 602c, and 602d. Accordingly, the second raw material is also divided into four channels.

As the first raw material channel 601 branched into the four first raw material channels 601a, 601b, 601c, and 601d further branches into two channels, the first raw material is also divided into two channels. At junctions 603a, 603b, 603c, and 603d, the first raw materials join so as to sandwich the second raw material, and the first raw material and the second raw material are mixed. The mixture of the first and second raw materials flows through the mixing channels 604a, 604b, 604c, and 604d downstream of the junctions 603a, 603b, 603c, and 603d, respectively. The mixture further flows through the downstream retention channels 605a, 605b, 605c, and 605d, respectively, and then merges as the retention channels 605a and 605b merge with the retention channel 605e on the front side. The mixture also merges as the retention channels 605c and 605d merge with the retention channel 605f on the back side. The mixture further merges as the retention channel 605e on the front side joins the retention channel 605f on the back side before the product outlet (mixing plate) 511, and is discharged from the product outlet (mixing plate) 511.

As mentioned above, by dividing the first raw material into two channels, the first raw material merges with the second raw material from different directions at the junctions 603a, 603b, 603c, and 603d. This can achieve good mixing. As a result, the interfacial area between the two types of raw material (the first raw material and the second raw material) is twice the interfacial area determined by the flow rate ratio (volume ratio). This can improve the mixing efficiency without making the structure so fine.

When the flow rate of the mixture is low or the reaction rate is high, the mixing channels 604a, 604b, 604c, and 604d can serve as reaction fields. When the flow rate of the mixture is high or the reaction rate is low, on the other hand, the reaction does not proceed sufficiently in the mixing channels 604a, 604b, 604c, and 604d, leaving the raw materials unreacted. The unreacted raw materials are introduced into the retention channels 605a, 605b, 605c, and 605d.

In FIGS. 5A to 5D and FIG. 6, the mixing channels 604a, 604b, 604c, and 604d (which may be hereinafter simply referred to as the “mixing channel 604”) have a representative diameter smaller than that of the retention channels 605a, 605b, 605c, and 605d (which may be hereinafter simply referred to as the “retention channel 605”). This allows the two raw materials to be quickly mixed by molecular diffusion. The retention channel 605 having a large representative diameter has a large channel cross-sectional area. This can easily increase the retention time of the mixture in the retention channel 605 and can also reduce the pressure loss in the retention channel 605. The representative diameter of the retention channel 605 may be the same as the representative diameter of the mixing channel 604, or may be selected as needed according to the target.

The first raw material channels 601a, 601b, 601c, and 601d (which may be hereinafter simply referred to as the “first raw material channels 601”) are each branched into two channels. This makes the channel internal volume of the first raw material channel 601 larger than that of the second raw material channels 602a, 602b, 602c, and 602d (which may be hereinafter simply referred to as the “second raw material channel 602”).

A ratio of the channel internal volume of the first raw material channel 601 to the channel internal volume of the second raw material channel 602 is preferably, but not limited to, close to the flow rate ratio (volume ratio) of the two types of raw material. The channel internal volume of the first raw material channel 601 and the channel internal volume of the second raw material channel 602 are preferably set to have equal or close values of pressure loss when the two types of raw material flow.

In this embodiment, the length of the first raw material channel 601 is set longer than the length of the second raw material channel 602. This makes the channel internal volume of the first raw material flow channel 601 larger than the channel internal volume of the second raw material flow channel 602, but the present invention is not limited thereto. For example, the channel internal volume of the first raw material flow channel 601 may be set larger than the channel internal volume of the second raw material flow channel 602 by setting the representative diameter of the first raw material flow channel 601 to be larger than the representative diameter of the second raw material flow channel 602. Alternatively, the channel internal volume of the first raw material flow channel 601 may be set larger than the channel internal volume of the second raw material flow channel 602 by using both the length and representative diameter of the first raw material channel 601. From the viewpoint of fabricating the mixing plate 104 by laser welding, in particular, and from the viewpoint of controlling the temperature of the fluid in the channels, however, the first raw material channel 601, the second raw material channel 602, and the mixing channel 604 preferably have the same width and depth (that is, the same representative diameter).

Moreover, the channel internal volume of the first raw material channel 413 in the preheating plate 103 and the channel internal volume of the second raw material channel 414 in the preheating plate 103 may be too large to be ignored, compared to the channel internal volume of the first raw material channel 601 or the channel internal volume of the second raw material channel 602. That is, there is a case where the channel internal volume of the first raw material channel 413 in the preheating plate 103 and the channel internal volume of the second raw material channel 414 in the preheating plate 103 also have to be taken into consideration as the channel internal volume of the first raw material channel and the channel internal volume of the second raw material channel until reaching the junctions 603a, 603b, 603c, and 603d. In such a case, the sum of the channel internal volume of the first raw material channel 413 in the preheating plate 103 and the channel internal volume of the first raw material channel 601 and the sum of the channel internal volume of the second raw material channel 414 in the preheating plate 103 and the channel internal volume of the second raw material channel 602 are preferably set to have equal or close values of pressure loss when the two types of raw material flow. A ratio of the sum of the channel internal volume of the first raw material channel 413 in the preheating plate 103 and the channel internal volume of the first raw material channel 601 to the sum of the channel internal volume of the second raw material channel 414 in the preheating plate 103 and the channel internal volume of the second raw material channel 602 is preferably close to the flow rate ratio (volume ratio) of the two types of raw material, but the present invention is not limited thereto.

In the microreactor 101, the channels (the first raw material channel and the second raw material channel) through which at least two types of raw material flow may have different volumes from the inlets (the first raw material inlet (preheating plate) 405 and the second raw material inlet (preheating plate) 406) for introducing the raw materials to the junctions 603a, 603b, 603c, and 603d (which may be hereinafter simply referred to as the “junction 603”) of the channels for mixing the raw materials. The relationship between the ratio of the channel internal volume of the first raw material channel to the channel internal volume of the second raw material channel and the flow rate ratio (volume ratio) of the two types of raw material will be described. The first raw material channel in the following description means the first raw material channel 601 and the first raw material channel 413 in the preheating plate 103 to be taken into account as necessary. The second raw material channel in the following description means the second raw material channel 602 and the second raw material channel 414 in the preheating plate 103 to be taken into account as necessary.

For example, description is given of a case where the channel internal volume ratio between the first raw material channel and the second raw material channel up to the junction 603 is changed under five conditions when the flow rate of the first raw material is 100 mL/min and the flow rate of the second raw material is 10 mL/min (the flow rate ratio is 10:1).

1) When both the first raw material channel and the second raw material channel have the same channel internal volume of 10 mL up to the junction 603, the first raw material reaches the junction 603 in 0.1 min=6 sec, while it takes 1 min=60 sec for the second raw material to reach the junction 603. In this case, the timing lag is 54 sec.

2) When the channel internal volume up to the junction 603 is 10 mL in the first raw material channel and 5 mL in the second raw material channel (volume ratio is 2:1), the first raw material reaches the junction 603 in 0.1 min=6 sec, while it takes 0.5 min=30 sec for the second material to reach the junction 603. In this case, the timing lag is 24 sec, which is slightly smaller than in 1).

3) When the channel internal volume up to the junction 603 is 10 mL in the first raw material channel and 2 mL in the second raw material channel (volume ratio is 5:1), the first raw material reaches the junction 603 in 0.1 min=6 sec, while it takes 0.2 min=12 sec for the second material to reach the junction 603. In this case, the timing lag is 6 sec, which is even smaller than in 2).

4) When the channel internal volume up to the junction 603 is 10 mL in the first raw material channel and 1 mL in the second raw material channel (volume ratio is 10:1), the first raw material reaches the junction 603 in 0.1 min=6 sec and the second raw material also reaches the junction 603 in 0.1 min=6 sec. In this case, the timing lag disappears.

5) When the channel internal volume up to the junction 603 is 10 mL in the first raw material channel and 0.5 mL in the second raw material channel (volume ratio is 20:1), the first raw material reaches the junction 603 in 0.1 min=6 sec, while the second raw material reaches the junction 603 in 0.05 min=3 sec. In this case, there is a timing lag of 3 sec, which is much smaller than in 1) and 2).

For example, description is given of a case where the sum of the flow rate of the first raw material and the flow rate of the second raw material is 110 mL/min and the flow rate ratio is changed under five conditions when the channel internal volume of the first raw material channel is 10 mL and the channel internal volume of the second raw material channel is 1 mL up to the junction 603 (the volume ratio is 10:1).

1) When both the first raw material and the second raw material have the same flow rate of 55 mL/min, the first raw material reaches the junction 603 in 0.182 min=10.9 sec, while the second raw material reaches the junction 603 in 0.018 min=1.1 sec. The timing lag is 9.8 sec.

2) When the flow rate of the first raw material is 73.3 mL/min and the flow rate of the second raw material is 36.7 ml/min (the flow rate ratio is 2:1), the first raw material reaches the junction 603 in 0.136 min=8.2 sec, while the second raw material reaches the junction 603 in 0.027 min=1.6 sec. In this case, the timing lag is 6.6 sec, which is slightly smaller than in 1).

3) When the flow rate of the first raw material is 91.7 mL/min and the flow rate of the second raw material is 18.3 mL/min (the flow rate ratio is 5:1), the first raw material reaches the junction 603 in 0.109 min=6.5 sec, while the second raw material reaches the junction 603 in 0.055 min=3.3 sec. In this case, the timing lag is 3.2 sec, which is even smaller than in 2).

4) When the flow rate of the first raw material is 100 mL/min and the flow rate of the second raw material is 10 mL/min (the flow rate ratio is 10:1), the first raw material reaches the junction 603 in 0.1 min=6 sec and the second raw material also reaches the junction 603 in 0.1 min=6 sec. In this case, the timing lag disappears.

5) When the flow rate of the first raw material is 104.8 mL/min and the flow rate of the second raw material is 5.2 mL/min (the flow rate ratio is 20:1), the first raw material reaches the junction 603 in 0.095 min=5.7 sec, while the second raw material reaches the junction 603 in 0.192 min=11.5 sec. In this case, the timing lag increases again to 5.8 sec, which is however smaller than in 1) and 2).

From the above, when the flow rate ratio (volume ratio) of two types of raw material is large, the lag in timing to reach the junction 603 can be reduced by providing a difference between the channel internal volume of the first raw material channel and the channel internal volume of the second raw material channel.

As described with reference to FIGS. 5C, 5D, and 6, the mixing plate 104 has a total of four parallel channel structures on both the front side and the back side. This shows that if the flow rate conditions are optimized in one channel structure, manufacturing can be performed using the same physical phenomenon under the fourfold flow rate conditions.

Hereinafter, description is given of a method for designing channels in a microreactor from lab process development to commercial production in pharmaceutical production.

Development steps in pharmaceutical production are divided into three stages: process development (production volume: several mL to 20 L), investigational new drug production (production volume: up to 50 L), and commercial production (production volume: 50 L or more). Furthermore, the process development is divided into three stages depending on the production volume (production volume: several mL, several tens mL, and up to 20 L).

One feature of the microreactor is that the same physical phenomenon can be utilized because parallelization (also called N-fold or numbering-up) of channels of the same shape is performed to increase the production volume. In reality, however, there is a flow rate difference of 30 times or more between the initial stage of process development (several mL/min) and commercial production (100 mL/min, equivalent to 50 L/8 h). Therefore, it is technically and economically unrealistic to increase the number of microreactors used in the initial stage of process development for commercial production. When shifting from the initial stage of process development (several mL/min) to the middle stage of process development (several tens mL/min), where there is the greatest difference in flow rate, it is preferable that the production volume is efficiently increased by scaling up the representative diameter of channels (channel cross-sectional area), instead of the numbering-up.

However, to make the linear velocity at the same level as the initial stage of process development in the middle stage of process development, the representative diameter needs to be tripled. In that case, the representative diameter becomes too large, leading to possible deterioration in the effect of miniaturization of the channels (the effect of the microreactor). To prevent this, it is preferable that the linear velocity that contributes to the shear force that may denature the raw materials and products is used as a parameter, and the reaction conditions are optimized within a range where the effect of the microreactor is maintained and the linear velocity does not increase too much.

Based on the above, when a microreactor is used, a microreactor with a flow rate of several mL/min is used to search for a reaction system and reaction conditions in the initial stage of process development where the production volume is several mL. In the middle stage where the production volume is increased from several mL to several tens mL, microreactors having a flow rate of several tens mL/min with different channel cross-sectional areas (different channel shapes) are used, thus bringing about the need to confirm scalability. Specifically, the reaction conditions are optimized by obtaining data using the linear velocity as a parameter. In the later stage where the production volume is up to 20 L, however, the scalability can be confirmed by performing long-time production using a microreactor with a production volume of several tens mL/min, which is the same as the middle stage where the production volume is several tens mL. Therefore, there is no need to confirm the scalability in the later stage where the production volume is up to 20 L, and only stability in long-time production is confirmed. Moreover, in the investigational new drug production and commercial production, microreactors obtained by numbering-up of the same channel shape are used. This can reduce confirmation work for validity due to scale-up, which is required in the conventional batch method.

In the investigational new drug production with a small production volume of up to 50 L, a microreactor is constructed by “internal numbering-up” where numbering-up of the channel structures is performed within the microreactor to verify the linear velocity range in which equivalence can be obtained. Furthermore, in the commercial production with a large production volume of 50 L or more, a microreactor is constructed by “external numbering-up” where numbering-up of the microreactor itself used in the investigational new drug production is performed, and the stability of the microreactor is confirmed considering the individual difference of the microreactor.

In the case of using a microreactor, when the production volume in the middle stage of process development is up to several tens mL/min, the structure of not only the mixing part for merging and mixing two types of raw material but also the retention part for setting the reaction time after mixing (the inner diameter and length of the tube on the downstream side of the microreactor) is determined along with the optimization of the reaction conditions. Therefore, at the stage of investigational new drug production, the internal numbering-up of the microreactor is performed according to the optimized conditions, and the mixing part and the retention part are integrated into the microreactor. Then, at the stage of commercial production, external numbering-up is performed on the microreactor including the retention part.

The most significant feature of the numbering-up is that the same channel structure is increased N-fold to increase the production volume and thus basically the same physical phenomenon is used, making it possible to eliminate the concern that different physical phenomena will lead to different results. In the internal numbering-up, however, since numbering-up of the channel structure is performed within the same microreactor, the microreactor and the microreactor system can be made compact, but there is a limit to the number of numbering-up due to structural restrictions. In the external numbering-up, on the other hand, the microreactor and microreactor system are parallelized, thus achieving flexibility on the number of numbering-up. However, the increased number of numbering-up leads to a risk associated with connection.

For example, in a microreactor with a flow rate of several mL/min in the early stage of process development, the representative diameter of the channel can be set to 0.2 mm. In a microreactor with a flow rate of several tens mL/min in the middle and later stages of process development, the representative diameter of the channel can be set to 0.5 mm. The mixing plate 104 and the microreactor 101 including the mixing plate described in this embodiment correspond to the case where four microreactors are arranged in parallel, each having a flow rate of several tens mL/min in the middle and later stages of process development. Such mixing plate and microreactor enable production with a flow rate level of 100 mL/min and can be used for investigational new drug production of up to 50 L. Furthermore, in commercial production of 50 L or more, the microreactor 101 can be used by external numbering-up of the microreactor 101 itself. Although the mixing plate 104 with a channel structure including four parallel channels has been described, the channel structure may include two parallel channels or three parallel channels depending on the optimized reaction conditions. The number of parallel channels may be five or more as long as the first raw material and the second raw material can be evenly sent to each mixing part.

### <Retention Plate>

As shown in FIGS. 7A and 7B, the retention plate 105 includes a retention plate upper plate 701 and a retention plate lower plate 702. Only holes are formed in the retention plate upper plate 701. Holes and grooves are formed in the retention plate lower plate 702 on both of the surface on the retention plate upper plate 701 side and the surface opposite thereto. Therefore, by integrating the retention plate upper plate 701 and the retention plate lower plate 702, a channel is formed by the retention plate upper plate 701 and the surface of the retention plate lower plate 702 on the retention plate upper plate 701 side.

As in the case of the preheating plate upper plate 401 and the preheating plate lower plate 402, the mixing plate upper plate 501, the mixing plate middle plate 502, and the mixing plate lower plate 503, the retention plate upper plate 701 and the retention plate lower plate 702 can be integrated without using any packing by various kinds of welding such as adhesion, fusion welding, pressure welding, ultrasonic welding, vibration welding, induction welding, high frequency welding, laser welding, and laser transmission welding. Among these, laser transmission welding using a light-transmitting resin and a light-absorbing resin can be suitably applied in this embodiment, as in the case of the preheating plate 103 and the mixing plate 104. The light-transmitting resin and the light-absorbing resin have already been described, and thus description thereof will be omitted here. In this embodiment, for example, it is preferable that white PE resin, white PP resin, or white PC resin is used as the material of the retention plate upper plate 701. It is also preferable that colored PE resin, colored PP resin, or colored PC resin such as black is used as the material of the retention plate lower plate 702. It is more preferable that white PE resin or white PP resin is used as the material of the retention plate upper plate 701, and that colored PE resin or colored PP resin is used as the material of the retention plate lower plate 702. Such retention plate upper plate and retention plate lower plate can be integrated by laser welding to obtain the retention plate 105 with corrosion resistance. The retention plate 105 can be thus protected from contamination by foreign materials such as an adhesive or the temperature control liquid from outside into the channel.

As shown in FIGS. 7A and 7C, a temperature control liquid channel 304 as well as a product inlet (retention plate) 705 and a product outlet (retention plate) 706, which penetrate the retention plate lower plate 702, are formed on the front side of the retention plate 105.

A temperature control liquid channel (retention plate) 707 penetrating to the back side is formed on the front side of the retention plate 105.

A temperature control liquid inlet (retention plate) 708 penetrating the retention plate lower plate 702 is formed on the front side of the retention plate 105. This temperature control liquid inlet (retention plate) 708 is communicated with the temperature control liquid channel 304 in the retention plate 105.

On the front side of the retention plate 105, a packing groove 305 is formed around each of the temperature control liquid channel 304, the product inlet (retention plate) 705, the product outlet (retention plate) 706, and the temperature control liquid channel (retention plate) 707. Twelve screw holes 112 penetrating to the back side for screwing the stacked plates are formed on the front side of the retention plate 105.

As shown in FIGS. 7A and 7C, the temperature control liquid channel 304 in the retention plate 105 is formed in a substantially cross-shape or substantially rectangular shape with a large area in the middle, on the front side of the retention plate 105.

The product inlet (retention plate) 705 is formed in the upper right part on the front side of the retention plate 105, as shown in FIGS. 7A and 7C.

The product outlet (retention plate) 706 is formed in the lower left part on the front side of the retention plate 105, as shown in FIGS. 7A and 7C.

As shown in FIGS. 7A and 7C, the temperature control liquid channel (retention plate) 707 and the temperature control liquid inlet (retention plate) 708 are formed in the upper left part on the front side of the retention plate 105. In this embodiment, the temperature control liquid channel (retention plate) 707 is formed above the temperature control liquid inlet (retention plate) 708 and closer to the outer edge.

As shown in FIGS. 7A and 7C, the screw holes 112 are formed at regular intervals along the outer edge of the retention plate 105 on the front side of the retention plate 105.

As shown in FIGS. 7A and 7D, a temperature control liquid outlet (retention plate) 709 is formed on the back side of the retention plate 105. As shown in FIG. 7D, the temperature control liquid outlet (retention plate) 709 is communicated with the temperature control liquid inlet (retention plate) 708 on the front side through a temperature control liquid channel 711.

The temperature control liquid channel 711 is formed from the temperature control liquid inlet (retention plate) 708 to the temperature control liquid outlet (retention plate) 709. The temperature control liquid channel 711 is bent substantially at a right angle, but does not need to be bent as long as the temperature control liquid inlet (retention plate) 708 is communicated with the temperature control liquid outlet (retention plate) 709.

The temperature control liquid channel (retention plate) 707 penetrating from the front side is formed on the back side of the retention plate 105. The twelve screw holes 112 penetrating from the front side for screwing the stacked plates are formed on the back side of the retention plate 105.

The temperature control liquid outlet (retention plate) 709 is formed in the lower left part of the retention plate 105, as shown in FIGS. 7B and 7D.

The temperature control liquid channel (retention plate) 707 is formed in the upper right part of the retention plate 105, as shown in FIGS. 7B and 7D.

As shown in FIG. 7D, the screw holes 112 are formed at regular intervals along the outer edge of the retention plate 105 on the back side of the retention plate 105.

By stacking the plates as shown in FIGS. 1, 2, and 9 with various packings (not shown) interposed between the plates, the surface of the mixing plate 104 on the retention plate 105 side and the surface of the retention plate 105 on the mixing plate 104 side form the temperature control liquid channel 304, and the channels in the mixing plate 104 and the retention plate 105 are communicated with each other. The product inlet (sump plate) 705 communicates with the product outlet (mixing plate) 511 of the mixing plate 104. The product outlet 706 communicates with the product channel (mixing plate) 508 of the mixing plate 104. The temperature control liquid channel (retention plate) 707 communicates with the temperature control liquid channel (mixing plate) 509 of the mixing plate 104.

The product (mixture) introduced from the product inlet (retention plate) 705 is discharged from the product outlet (retention plate) 706 (FIGS. 7A and 7C) through retention channels 710a and 710b (FIGS. 7B and 7D). The temperature control liquid introduced from the temperature control liquid channel 304 to the temperature control liquid inlet (retention plate) 708 is discharged from the temperature control liquid outlet (retention plate) 709 (FIGS. 7B and 7D) through the temperature control liquid channel 711.

As shown in FIG. 7D, upper and lower retention channels 710a and 710b are formed on the back side of the retention plate 105 with the same channel internal volume (inner volume) for further advancing the mixing of the first raw material and the second raw material. The product is divided into two parts as the channel communicated with the product inlet (retention plate) 705 branches into the two retention channels 710a and 701b. The retention channels 710a and 701b join before the product outlet (retention plate) 706 and are then communicated with the product outlet (retention plate) 706.

In the microreactor 101, at least one of the plurality of plates (specifically, the retention plate 105) has channels (the retention channels 710a and 710b), through which a solution containing at least two types of raw material mixed therein flows, on one surface (back side), and a channel (the temperature control liquid channel 304), through which the heat medium flows, on a surface (front side) opposite to the surface described above.

As described above, the two branched retention channels 710a and 710b increase the channel cross-sectional area, thus making it possible to increase the retention time of the product and also to reduce the pressure loss in the retention channels 710a and 710b. The retention channels 710a and 710b can be selected as needed based on the flow rates of the first and second raw materials, the reaction time required for the reaction to proceed, and the like. For example, the number of branches of the retention channel 710 is not limited to two, and may be three or more. Alternatively, the retention channel 710 does not need to be branched. The retention plate 105 is not limited to one, and a plurality of retention plates 105 may be used.

The representative diameter of the channels in the retention plate 105 is not limited to one diameter. Different representative diameters may be used on the upstream and downstream sides. Channels having three or more different representative diameters may be used. In this case, as the reaction time elapses, the heat of mixing or reaction resulting from the merging of the first raw material and the second raw material decreases. Therefore, from the viewpoint of reducing the entire pressure loss, it is preferable to increase the representative diameter of the channels toward the downstream side. When the residence time required for the reaction to proceed is very long, the heat of mixing or reaction is large. It is possible to reduce the complexity and cost of stacking a plurality of retention plates 105 by using the retention plate 105 only on the upstream side where the effect of the microreactor 101 needs to be used and by using a commercially available tube coil or the like on the downstream side where the heat of mixing or reaction is small. When the residence time required for the reaction to proceed is short, on the other hand, the reaction may be completed in the retention channel 605 in the mixing plate 104. In such a case, the retention plate 105 does not sometimes need to be used.

### <Back Cover Plate>

As shown in FIGS. 8A and 8B, a temperature control liquid channel 304 and a temperature control liquid outlet (back cover plate) 804 that does not penetrate to the back side are formed on the front side of the back cover plate 106.

The temperature control liquid outlet (back cover plate) 804 is formed in the upper left part as shown in FIGS. 8A and 8B.

As shown in FIGS. 8A and 8B, the temperature control liquid channel 304 in the back cover plate 106 is formed in a substantially cross-shape or substantially rectangular shape with a large area in the middle, on the front side of the back cover plate 106.

A packing groove 305 is formed around each of the temperature control liquid channel 304 and the temperature control liquid outlet (back cover plate) 804 on the front side of the back cover plate 106.

Moreover, on the front side of the back cover plate 106, twelve screw holes 112 are formed penetrating to the back side for screwing the stacked plates.

Similarly, as shown in FIG. 8C, twelve screw holes 112 penetrating to the front side for screwing the stacked plates are formed on the back side of the back cover plate 106.

The screw holes 112 are formed at regular intervals along the outer edge of the back cover plate 106, as shown in FIGS. 8A to 8C.

Furthermore, as shown in FIG. 8A, a channel 803 is formed in the back cover plate 106 from the temperature control liquid channel 304 to the temperature control liquid outlet (back cover plate) 804 that does not penetrate to the back side.

By stacking the plates as shown in FIGS. 1, 2, and 9 with various packings (not shown) interposed between the plates, the surface of the retention plate 105 on the back cover plate 106 side and the surface of the back cover plate 106 on the retention plate 105 side form the temperature control liquid channel 304, and the channels in the retention plate 105 and the back cover plate 106 are communicated with each other. The temperature control liquid outlet (back cover plate) 804 is communicated with the temperature control liquid channel (retention plate) 707 in the retention plate 105.

The temperature control liquid introduced from the temperature control liquid channel 304 is discharged from the temperature control liquid channel 304 to the temperature control liquid outlet (back cover plate) 804 through the channel 803.

The function of the back cover plate 106 can also be incorporated in the retention plate 105 to discharge the temperature control liquid to the temperature control liquid channel (retention plate) 707 in the retention plate 105, thus eliminating the need to use the back cover plate 106.

### <Advantageous Effects of Microreactor>

With the above configuration, in the microreactor 101 according to this embodiment, the first raw material and the second raw material introduced from the first raw material inlet 107 and the second raw material inlet 108 on the front side of the front cover plate 102 are joined and mixed inside the microreactor 101. The mixed first and second raw materials are discharged as a product (mixture) from the product outlet 109 on the front side of the front cover plate 102. In the microreactor 101, the temperature control liquid introduced from the temperature control liquid inlet 110 on the front side of the front cover plate 102 is discharged from the temperature control liquid outlet 111 on the front side of the front cover plate 102 after flowing through the microreactor 101. The temperature of the microreactor 101 can be controlled by passing the temperature control liquid through the microreactor 101. This eliminates the need to control the temperature of the microreactor by immersing the microreactor in the temperature control liquid as in the related art, thus preventing contamination of the raw materials or product by the temperature control liquid. Such a structure of the microreactor 101 eliminates the need for joints, connection tubes or the like for connecting plates (reaction channel plates) in which the raw materials and product flow, unlike the related art. Such a structure of the microreactor 101 also eliminates the need for joints and connection tubes for connecting plates (temperature control plates) in which the temperature control liquid flows.

Moreover, in the microreactor 101, the preheating plate 103, the mixing plate 104, and the retention plate 105 are integrated, respectively. This can prevent leakage from each plate and contamination by foreign substances such as an adhesive and the temperature control liquid from outside into the channels. Therefore, the microreactor 101 can be used without a risk of contamination by foreign substances such as the temperature control liquid even when handling a highly corrosive substance or synthesis reaction that requires careful handling or when there is a risk of cross-contamination.

Furthermore, in the microreactor 101, the first raw material inlet 107, the second raw material inlet 108, the product outlet 109, the temperature control liquid inlet 110, and the temperature control liquid outlet 111 are formed on the front side of the front cover plate 102. Therefore, the liquid feeder for feeding the raw materials and temperature control liquid and the joints and connecting tubes for connecting containers can all be mounted on the front side of the front cover plate 102. This reduces restrictions on the installation location of the microreactor 101 and the access direction to the microreactor 101.

Therefore, the present invention can provide a microreactor which can reduce workload of an operator without a risk of contamination by foreign substances such as a temperature control liquid.

In this embodiment, the microreactor for mixing two types of raw material has been described, but three or more types of raw material may be used. In this case, for example, raw materials with high flow rates may be sequentially merged so as to sandwich a raw material with the lowest flow rate. The channel internal volume (inner volume) of the channel through which the raw material flows may be set larger as the flow rate increases.

In this embodiment, the mixing plate 104 with a channel structure including four parallel channels has been described, but the channel structure may include two parallel channels or three parallel channels depending on the optimized reaction conditions. The number of parallel channels may be five or more as long as the first raw material and the second raw material can be evenly sent to each mixing part.

Moreover, in this embodiment, the microreactor 101 including the front cover plate 102, the preheating plate 103, the mixing plate 104, the retention plate 105, and the back cover plate 106 has been described, but either one or both of the preheating plate 103 and the retention plate 105 may be omitted. Although the microreactor 101 having one preheating plate 103 and one retention plate 105 has been described, a plurality of preheating plates 103 and a plurality of retention plates 105 may be used. Furthermore, the back cover plate 106 does not need to be used by incorporating the function of the back cover plate 106 in the retention plate 105.

### <Product Production Method>

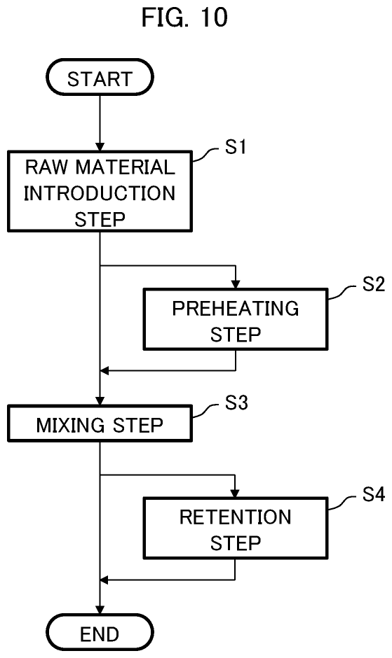

Next, with reference to FIG. 10, a product production method according to one embodiment of the present invention will be described. FIG. 10 is a flowchart showing an example of the product production method according to the embodiment of the present invention. In the following description of the product production method, detailed description of the elements that have already been described may be omitted.

The product production method uses the microreactor 101 described above to introduce and mix at least two types of raw material, thus producing a product.

Specifically, as shown in FIG. 10, the product production method includes a raw material introduction step S1 and a mixing step S3. The product production method may also include a preheating step S2 between the raw material introduction step S1 and the mixing step S3 as shown in FIG. 10. Moreover, the product production method may include a retention step S4 after the mixing step S3 as shown in FIG. 10. These steps will be described below.

### <Raw Material Introduction Step>

The raw material introduction step S1 is a step of introducing at least two types of raw material (for example, a first raw material and a second raw material) into the microreactor 101. The introduction of the first and second raw materials into the microreactor 101 can be performed, for example, from the first raw material inlet 107 and the second raw material inlet 108 on the front side of the front cover plate 102, respectively.

### <Mixing Step>

The mixing step S3 is a step of mixing the at least two types of raw material (for example, the first and second raw materials) introduced into the microreactor 101 to obtain a mixture (product). The mixing of the first and second raw materials is performed in the mixing channels 604a, 604b, 604c, and 604d and the retention channels 605a, 605b, 605c, and 605d in the mixing plate 104.

### <Preheating Step>

The preheating step S2 is a step of pre-adjusting (for example, warming) the at least two types of raw material (for example, the first and second raw materials) introduced into the microreactor 101 to a predetermined temperature suitable for reaction. Although the term “preheating” is used, the predetermined temperature suitable for reaction may be lower than ordinary temperature (for example, room temperature (25° C.)) (and may be, for example, 4° C. or lower or 0° C. or lower). In that case, any refrigerant may be used as the temperature control liquid for cooling to set the temperature of the first and second raw materials to be lower than ordinary temperature. Thus, as used herein, the term “preheating” includes cooling and the act of cooling (that is, including the act of adjusting the temperature of the raw material). The preheating of the first and second raw materials is performed in the first raw material channel 413 and the second raw material channel 414 in the preheating plate 103. This preheating step S2 does not need to be included in the product production method when the temperature can be controlled to a predetermined temperature before the first raw material and the second raw material merge (in the mixing plate 104) in the mixing step S3.

### <Retention Step>

The retention step S4 is a step of further advancing the mixing of the at least two types of raw material (for example, the first and second raw materials) introduced into the microreactor 101. Further mixing of the first and second raw materials is carried out in the retention channels 710a and 710b. When the residence time required for the reaction to proceed is short, the reaction may be completed (inside the mixing plate 104) in the mixing step S3. In such a case, the retention step S4 does not need to be included in the product production method.

The present invention can provide a product production method which can reduce the workload of the operator without a risk of contamination by foreign substances such as the temperature control liquid as described above by use of the microreactor 101.

### EXAMPLE

### Manufacturing Example of Microreactor

A manufacturing example (one example) of a microreactor will be described below, but the present invention is not limited to the following example.

According to the embodiment described above, a PE microreactor 101 is manufactured using a white PE plate and a black PE plate. In the microreactor 101, a preheating plate 103, a mixing plate 104, and a retention plate 105 are integrated by laser transmission welding.

A first raw material channel 601, a second raw material channel 602, and a mixing channel 604 each have a representative diameter of 0.5 mm. A first raw material channel 413, a second raw material channel 414, a retention channel 605, and retention channels 710a and 710b each have a representative diameter of 2 mm.

A front cover plate 102, the preheating plate 103, the mixing plate 104, the retention plate 105, and a back cover plate 106 are stacked and screwed together using PEEK screws and plain washers (washers). Various packings provided between the plates are made of perfluoroelastomer (FFKM) or fluororubber (FKM).

A first raw material inlet 107 and a second raw material inlet 108 of the PE microreactor 101 are each connected to a 25 mL glass syringe with a polytetrafluoroethylene (PTFE) joint and a PTFE connecting tube having an outside diameter of 3 mm, an inside diameter of 2 mm, and a length of 1.2 m. A pressure sensor capable of measuring up to 500 kPa is installed between the first raw material inlet 107 and the glass syringe. A PTFE connecting tube having an outside diameter of 3 mm, an inside diameter of 2 mm, and a length of 0.6 m is connected to a product outlet 109 by a PTFE joint.

A double syringe pump is used to suck pure water into the glass syringe and send it to the first raw material inlet 107 and the second raw material inlet 108 of the PE microreactor 101 at an equal flow rate, thus generating a product through the microreactor 101. A value indicated by the pressure sensor while the pure water is being sent is evaluated as a pressure loss of the PE microreactor 101. The evaluation is conducted at room temperature (24° C.) without circulating a temperature control liquid.

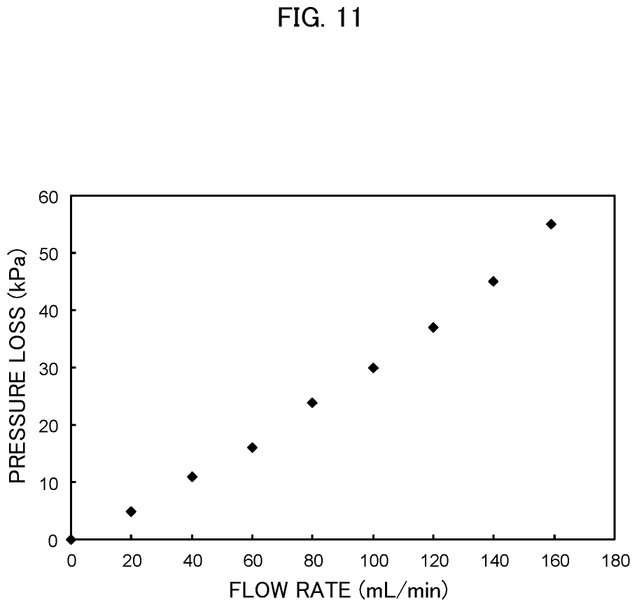

FIG. 11 is a graph showing the pressure loss when the pure water is sent to the PE microreactor 101 manufactured in the example. In FIG. 11, the horizontal axis represents the sum of the flow rate of the first raw material and the flow rate of the second raw material, while the vertical axis represents the pressure loss when the pure water is sent to the microreactor 101.

Even though the PE microreactor 101 includes not only the mixing plate 104 but also the preheating plate 103 and the retention plate 105, the pressure loss is about 30 kPa at the flow rate of 100 mL/min (investigational drug production level of up to 50 L) as shown in FIG. 11.

As described above, the manufactured microreactor 101 has a small pressure loss when the pure water is sent. Therefore, the reaction time required to complete the reaction is very long. The microreactor 101 is fully applicable even when a plurality of retention plates 105 or a retention part such as a commercially available tube coil has to be also provided on the downstream side. It is confirmed that the microreactor 101 is also applicable for a reaction system in which a plurality of microreactors 101 have to be used in order to use a plurality of types of raw material, such as a three-liquid reaction system in which two microreactors 101 are connected in series for reaction, or a reaction system in which the pressure loss may increase due to the use of a raw material with a viscosity higher than that of pure water.

In the manufactured microreactor 101, the preheating plate 103, the mixing plate 104, and the retention plate 105 are integrated, respectively, and thus there is no leakage from each plate. It is therefore conceivable that contamination by foreign materials such as an adhesive or the temperature control liquid from outside into the channel can be prevented. Therefore, the microreactor 101 can be used without a risk of contamination by foreign materials such as the temperature control liquid even when handling a highly corrosive substance or synthesis reaction that requires careful handling or when there is a risk of cross-contamination.

Moreover, in the manufactured microreactor 101, the first raw material inlet 107, the second raw material inlet 108, the product outlet 109, the temperature control liquid inlet 110, and the temperature control liquid outlet 111 are formed on the front side of the front cover plate 102. Therefore, the liquid feeder for sending the raw materials and the temperature control liquid and the joints and connecting tubes for connecting containers can all be attached on the front side of the front cover plate 102. This reduces restrictions on the installation location of the microreactor 101 and the access direction to the microreactor 101.

The manufactured microreactor 101 can thus reduce the workload of the operator without a risk of contamination by foreign materials such as the temperature control liquid.

The microreactor and the product production method according to the present invention have been described above in detail with reference to the embodiment and example. The present invention, however, is not limited to the embodiment and example described above, but includes various modifications. For example, the embodiment has been described in detail for describing the present invention in an easy-to-understand manner, and is not necessarily limited to the embodiment having the entire configurations described. A part of configurations of a certain embodiment can be replaced with configurations of other embodiments. Likewise, the configurations of the other embodiments can be added to the configurations of the certain embodiment. Moreover, other configurations can be added to, deleted from, or replaced with a part of the configurations of each embodiment.

### REFERENCE SIGNS LIST

101 microreactor
102 front cover plate
103 preheating plate
104 mixing plate
105 retention plate
106 back cover plate
107 first raw material inlet
108 second raw material inlet
109 product outlet
110 temperature control liquid inlet
111 temperature control liquid outlet
112 screw hole
113 notch
114 thermocouple insertion port
303 channel from temperature control liquid inlet to temperature control liquid channel
304 temperature control liquid channel
305 packing groove
401 preheating plate upper plate
402 preheating plate lower plate
405 first raw material inlet (preheating plate)
406 second raw material inlet (preheating plate)
407 product channel (preheating plate)
408 temperature control liquid channel (preheating plate)
409 temperature control liquid inlet (preheating plate)
410 first raw material outlet (preheating plate)
411 second raw material outlet (preheating plate)
412 temperature control liquid outlet (preheating plate)
413 first raw material channel
414 second raw material channel
415 temperature control liquid channel
501 mixing plate upper plate
502 mixing plate middle plate
503 mixing plate lower plate
506 first raw material inlet (mixing plate)
507a, 507b second raw material inlet (mixing plate)
508 product channel (mixing plate)
509 temperature control liquid channel (mixing plate)
510 temperature control liquid inlet (mixing plate)
511 product outlet (mixing plate)
512 temperature control liquid outlet (mixing plate)
513 temperature control liquid channel
601, 601a, 601b, 601c, 601d first raw material channel
602, 602a, 602b, 602c, 602d second raw material channel
603, 603a, 603b, 603c, 603d junction
604, 604a, 604b, 604c, 604d mixing channel
605, 605a, 605b, 605c, 605d, 605e, 605f retention channel
701 retention plate upper plate
702 retention plate lower plate
705 product inlet (retention plate)
706 product outlet (retention plate)
707 temperature control liquid channel (retention plate)
708 temperature control liquid inlet (retention plate)
709 temperature control liquid outlet (retention plate)
710a, 710b retention channel
711 temperature control liquid channel
803 channel from temperature control liquid channel to temperature control liquid outlet (back cover plate)
804 temperature control liquid outlet (back cover plate)

1. A microreactor configured to produce a product by mixing at least two types of raw material, the microreactor comprising:
plates which are stacked on each other,
wherein one of the plates includes: an inlet which allows the raw material to be introduced into the inlet; a product outlet which allows a solution containing the product to be discharged from the product outlet; a temperature control liquid inlet which allows a heat medium for temperature control to be introduced into the temperature control liquid inlet; and a temperature control liquid outlet which allows the heat medium to be discharged from the temperature control liquid outlet, and
wherein the inlet, the product outlet, the temperature control liquid inlet, and the temperature control liquid outlet are located on the same face of the one of the plates.

2. The microreactor according to claim 1, wherein at least one of the plates has a first face and a second face opposite to the first face, and
wherein the at least one of the plates includes: on the first face a first channel which allows a solution containing the at least two types of raw material which are joined together to flow through the first channel; and on the second face a second channel which allows the heat medium to flow through the second channel.

3. The microreactor according to claim 1, wherein at least one of the plates has a first face and a second face opposite to the first face, and
wherein the at least one of the plates includes: on the first face a first channel which allows at least one of the at least two types of raw material to flow through the first channel; and on the second face a second channel which allows the heat medium to flow through the second channel.

4. The microreactor according to claim 1, wherein one of the plates has a first face and a second face opposite to the first face,
wherein the one of the plates includes: channels which allow the at least two types of raw material to be mixed in the channels, and
wherein one of the channels is located on the first face and another of the channels is located on the second face.

5. The microreactor according to claim 3, wherein one of channels of the microreactor allows one of the at least two types of raw material to flow through the one of channels,
the one of channels has a first volume of from a first inlet of the one of channels to a junction of the channels, the first inlet allowing the one of the at least two types of raw material to be introduced into the first inlet,
wherein the junction allows the at least two types of raw material to be mixed in the junction,
wherein another of the channels allows another of the at least two types of raw material to flow through the another of the channels,
wherein the another of the channels has a second volume of from a second inlet of the another of the channels to the junction, the second inlet allowing the another of the at least two types of raw material to be introduced into the second inlet, and
wherein the first volume is different from the second volume.

6. The microreactor according to claim 1, wherein
the plates include at least one of stainless steel, silicon, gold, glass, hastelloy, silicon resin, acrylic, polycarbonate, cycloolefin polymer, polyethylene, polypropylene, methyltenpen polymer, fluororesin, polyetheretherketone resin, metal having a glass-lined surface, metal having a surface coated with nickel or gold, or silicon having an oxidized surface.

7. A method for producing a product by using the microreactor according to claim 1 comprising:
introducing at least two types of raw material; and
producing a product by mixing the at least two types of raw material.

8. The microreactor according to claim 4, wherein one of channels of the microreactor allows one of the at least two types of raw material to flow through the one of channels,
the one of channels has a first volume of from a first inlet of the one of channels to a junction of the channels, the first inlet allowing the one of the at least two types of raw material to be introduced into the first inlet,
wherein the junction allows the at least two types of raw material to be mixed in the junction,
wherein another of the channels allows another of the at least two types of raw material to flow through the another of the channels,
wherein the another of the channels has a second volume of from a second inlet of the another of the channels to the junction, the second inlet allowing the another of the at least two types of raw material to be introduced into the second inlet, and
wherein the first volume is different from the second volume.
